(19) United States
(12) Patent Application Publication
(10) Pub. No.: US 2024/0055562 A1
(43) Pub. Date: Feb. 15, 2024

(54) DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR); No Kyung PARK, Yongin-si (KR)

(73) Assignee: Samsung Display Co., LTD., Yongin-si (KR)

(21) Appl. No.: 18/310,602

(22) Filed: May 2, 2023

(30) Foreign Application Priority Data
Aug. 12, 2022 (KR) 10-2022-0101654

(51) Int. Cl. H01L 33/38; H01L 25/075; H01L 25/16; H01L 33/62; H01L 27/12

(52) U.S. Cl. CPC H01L 33/382; H01L 25/0753; H01L 25/167; H01L 33/62; H01L 27/124; H01L 27/1255

(57) ABSTRACT

A display device includes a pixel circuit of a first pixel formed of: a first meta layer, an active layer on the first metal layer, and a second metal layer on the active layer, a first electrode formed of: a third metal layer on the second metal layer and overlapping the pixel circuit of the first pixel, a pixel circuit of a second pixel formed of: the first metal layer, the active layer, and the second metal layer and spaced apart from the pixel circuit of the first pixel in a first direction, a second electrode formed of the third metal layer and overlapping the pixel circuit of the second pixel, an alignment line formed of the third metal layer and extending in the first direction, and light emitting elements aligned between the alignment line and the first electrode and between the alignment line and the second electrode.

### CROSS-REFERENCE TO RELATED APPLICATION(S)

This application claims priority to and benefits of Korean Patent Application No. 10-2022-0101654 under 35 U.S.C. § 119, filed on Aug. 12, 2022, in the Korean Intellectual Property Office, the entire contents of which are incorporated herein by reference.

### BACKGROUND

### 1. Technical Field

Embodiments relate to a display device.

### 2. Description of the Related Art

With the advance of information-oriented society, display devices for displaying images in various ways have been demanded more and more. For example, display devices are implemented in various electronic devices such as smartphones, digital cameras, laptop computers, navigation devices, and smart televisions. The display devices may be flat panel display devices such as a liquid crystal display device, a field emission display device and an organic light emitting display device. Among the flat panel display devices, in the light emitting display device, since each of pixels of a display panel includes a light emitting element capable of emitting light by itself, an image may be displayed without a backlight unit providing light to the display panel. The light emitting element may be an organic light emitting diode formed of an organic material as a fluorescent material and an inorganic light emitting diode formed of an inorganic material as a fluorescent material.

### SUMMARY

Embodiments provide a display device capable of improving image quality by reducing the coupling capacitance between pixel circuits and preventing horizontal crosstalk (or coupling).

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment, a display device may include a pixel circuit of a first pixel formed of: a first meta layer disposed on a substrate, an active layer disposed on the first metal layer, and a second metal layer disposed on the active layer, a first electrode formed of a third metal layer disposed on the second metal layer and overlapping a pixel circuit of the first pixel, a pixel circuit of a second pixel formed of: the first metal layer, the active layer, and the second metal layer and spaced apart from the pixel circuit of the first pixel in the first direction, a second electrode formed of the third metal layer and overlapping the pixel circuit of the second pixel, an alignment line formed of the third metal layer and extending in the first direction, and a plurality of light emitting elements disposed on the third metal layer and aligned between the alignment line and the first electrode and aligned between the alignment line and the second electrode.

The pixel circuit of the first pixel may include a first capacitor electrode formed of the active layer and a second capacitor electrode formed of the first metal layer. The first electrode may overlap the first capacitor electrode of the first pixel and may be electrically connected to the second capacitor electrode of the first pixel.

The display device may further include a low potential line formed of the second metal layer and extending in a second direction intersecting the first direction, a first contact electrode formed of a fourth metal layer disposed on the third metal layer and connected between the first electrode and the plurality of light emitting elements, and a second contact electrode formed of the fourth metal layer and connected between the plurality of light emitting elements and the low potential line.

The display device may further include a pixel circuit of a third pixel formed of the first metal layer, the active layer and the second metal layer and disposed between the pixel circuit of the first pixel and the pixel circuit of the second pixel, and a third electrode formed of the third metal layer and overlapping the pixel circuit of the third pixel.

The display device may further include a fourth electrode formed of the third metal layer and spaced apart from the third electrode and connected to the pixel circuit of the third pixel, wherein the alignment line may be disposed between the third electrode and the fourth electrode.

The pixel circuit of the second pixel may include a first capacitor electrode formed of the active layer and a second capacitor electrode formed of the first metal layer. The second electrode may overlap the first capacitor electrode of the second pixel and may be electrically connected to the second capacitor electrode of the second pixel.

The display device may further include a bank disposed on the first electrode and the second electrode and may include an open portion disposed between the first electrode and the second electrode.

The bank may further include a light emitting opening extending in the first direction. The plurality of light emitting elements may be disposed in the light emitting opening.

The display device may further include a gate line formed of the second metal layer and extending in a second direction intersecting the first direction and supplying a gate signal to the pixel circuit of the first pixel and the pixel circuit of the second pixel. The gate line may be disposed between the pixel circuit of the first pixel and the pixel circuit of the second pixel.

According to an embodiment, a display device may include a pixel circuit of a first pixel formed of a first metal layer disposed on a substrate, an active layer disposed on the first metal layer, and a second metal layer disposed on the active layer, a first electrode formed of a third metal layer disposed on the second metal layer and overlapping the pixel circuit of the first pixel, a pixel circuit of a second pixel formed of: the first metal layer, the active layer, and the second metal layer and spaced apart from the pixel circuit of the first pixel in a first direction, a second electrode formed of the third metal layer and overlapping the pixel circuit of the second pixel, and a bank disposed on the first electrode and the second electrode and including an open portion disposed between the first electrode and the second electrode.

The display device may further include an alignment line formed of the third metal layer and spaced apart from the first electrode and the second electrode in a second direction intersecting the first direction, and a plurality of light emitting elements aligned between the alignment line and the first electrode.

The bank may further include a light emitting opening overlapping an area between the alignment line and the first electrode. The plurality of light emitting elements may be disposed in the light emitting opening.

The display device may further include a low potential line formed of the second metal layer and extending in the second direction intersecting the first direction, a first contact electrode formed of a fourth metal layer on the third metal layer and connected between the first electrode and the plurality of light emitting elements, and a second contact electrode formed of the fourth metal layer and connected between the plurality of light emitting elements and the low potential line.

The display device may further include an alignment line formed of the third metal layer and spaced apart from the first electrode and the second electrode in a second direction intersecting the first direction, and a plurality of light emitting elements aligned between the alignment line and the second electrode.

The display device may further include a low potential line formed of the second metal layer and extending in the second direction intersecting the first direction, a first contact electrode formed of a fourth metal layer on the third metal layer and connected between the second electrode and the plurality of light emitting elements, and a second contact electrode formed of the fourth metal layer and connected between the plurality of light emitting elements and the low potential line.

The pixel circuit of the first pixel may include a first capacitor electrode formed of the active layer and a second capacitor electrode formed of the first metal layer. The first electrode may overlap the first capacitor electrode of the first pixel and may be electrically connected to the second capacitor electrode of the first pixel.

The pixel circuit of the second pixel may include a first capacitor electrode formed of the active layer and a second capacitor electrode formed of the first metal layer. The second electrode may overlap the first capacitor electrode of the second pixel and may be electrically connected to the second capacitor electrode of the second pixel.

According to an embodiment, a display device may include a first voltage line formed of a first metal layer disposed on a substrate, a first transistor comprising a drain electrode formed of an active layer disposed on the first metal layer and electrically connected to the first voltage line; a source electrode formed of the active layer, and a gate electrode formed of a second metal layer on the active layer, a first capacitor electrode formed of the active layer and electrically connected to the gate electrode of the first transistor, a second capacitor electrode formed of the first metal layer and overlapping the first capacitor electrode, a first electrode formed of a third metal layer on the second metal layer and overlapping the first capacitor electrode and electrically connected to the second capacitor electrode, an alignment line formed of the third metal layer and extending in a first direction, and a plurality of light emitting elements aligned between the alignment line and the first electrode on the third metal layer.

The display device may further include a data line formed of the first metal layer and extending in the first direction, and a second transistor electrically connecting the data line and the first capacitor electrode.

The display device may feather include an initialization voltage line formed of the first metal layer and extending in the first direction, and a third transistor electrically connecting the initialization voltage line and the second capacitor electrode.

In accordance with the display device according to embodiments, by forming a double capacitor between the gate electrode and the source electrode of the first transistor, the display device may be capable of ensuring capacitance capacity to reduce the coupling capacitance between pixel circuits and preventing horizontal crosstalk for coupling) to improve image quality.

However, the effects of the disclosure are not limited to the aforementioned effects, and various other effects are included in the description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a contact portion of a vertical gate line and a horizontal gate line in a display device according to an embodiment;

FIG. 3 is a schematic diagram illustrating pixels and lines of a display device according to an embodiment;

FIG. 4 is a schematic diagram of an equivalent circuit of a pixel of a display device according to an embodiment;

FIGS. 5 and 6 are schematic plan views illustrating a portion of a display area in a display device according to an embodiment;

FIG. 7 is a schematic cross-sectional view taken along line I-I′ of FIGS. 5 and 6;

FIG. 8 is a schematic cross-sectional view taken along line II-IF of FIGS. 5 and 6;

FIG. 9 is a schematic plan view illustrating a first metal layer, an active layer, a second metal layer, a third metal layer and a bank in a display device according to an embodiment;

FIGS. 10 to 13 are schematic diagrams illustrating a manufacturing process of a light emitting element layer in a display device according to an embodiment;

FIG. 14 is a schematic cross-sectional view taken along line of FIGS. 9 and 13;

FIG. 15 is a schematic cross-sectional view taken along line IV-IV′ of FIGS. 9 and 13; and

FIG. 16 is a schematic plan view illustrating a third metal layer, a bank, a light emitting element, a fourth metal layer and a separation portion in a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. The term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” may encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure are described with reference to the accompanying drawings.

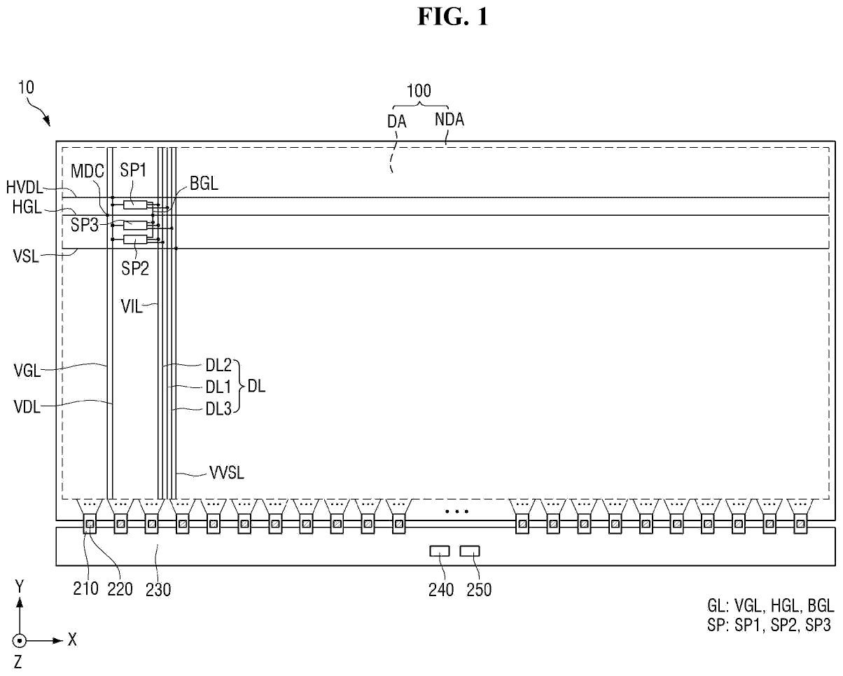

FIG. 1 is a schematic plan view illustrating a display device according to an embodiment.

The terms “above,” “top” and “top surface” as used herein refer to an upward direction (i.e., a Z-axis direction) with respect to the display device 10. The terms “below,” “bottom” and “bottom surface” as used herein refer to a downward direction (i.e., a direction opposite to the Z-axis direction) with respect to the display device 10. Further, the terms “left,” “right,” “upper,” and “lower” respectively indicate corresponding directions on the surface of the display device 10. For example, the term “left” indicates a direction opposite to an X-axis direction, the term “right” indicates the X-axis direction, the term “upper” indicates a Y-axis direction, and the term “lower” indicates a direction opposite to the Y-axis direction.

Referring to FIG. 1, a display device 10, as a device for displaying a moving or still image, may be implemented as a display screen of various products such as a television, a laptop computer, a monitor, a billboard, and an Internet of Things (IoT) device as well as portable electronic devices such as a mobile phone, a smartphone, a tablet personal computer (PC), a smart watch, a watch phone, a mobile communication terminal, an electronic notebook, an eBook reader, a portable multimedia player (PMP), a navigation device, and an ultra-mobile PC (UMPC).

The display device 10 may include a display panel 100, a flexible film 210, a display driver 220, a circuit board 230, a timing controller 240, and a power supply unit 250.

The display panel 100 may have a rectangular shape in plan view. For example, the display panel 100 may have a rectangular shape having long sides in a first direction (e.g., X-axis direction) and short sides in a second direction (e.g., Y-axis direction) in plan view. A corner formed by the long side in the first direction (e.g., X-axis direction) and the short side in the second direction (e.g., Y-axis direction) may be right-angled or rounded with a certain curvature. The planar shape of the display panel 100 is not limited to the rectangular shape, and may be formed in another polygonal shape, a circular shape or an elliptical shape. For example, the display panel 100 may be formed to be flat, but embodiments are not limited thereto. In another example, the display panel 100 may be bent with a certain curvature.

The display panel 100 may include a display area DA and a non-display area NDA.

The display area DA, which is an area for displaying an image, may be defined as the central area of the display panel 100. The display area DA may include a pixel SP, gate lines GL, data lines DL, an initialization voltage line VIL, a first voltage line VDL, a horizontal voltage line HVDL, and a vertical voltage line VVSL, and a second voltage line VSL. The pixel SP may be formed for each pixel area crossed by the data lines DL and the gate lines GL. The pixels SP may include first to third pixels SP1, SP2, and SP3. Each of the first to third pixels SP1, SP2, and SP3 may be connected (e.g., electrically connected) to at least one of the gate lines GL and at least one of the data lines DL. Each of the first to third pixels SP1, SP2, and SP3 may be defined as a minimum unit area that outputs light.

The first pixel SP1 may emit light of a first color such as red light, the second pixel SP2 may emit light of a second color such as green light, and the third pixel SP3 may emit light of a third color such as blue light. The pixel circuits PXC of the first pixel SP1, the third pixel SP3 and the second pixel SP2 may be sequentially arranged in the opposite direction of the second direction (e.g., Y-axis direction), but the arrangement direction of the pixel circuits PXC is not limited thereto.

The gate lines GL may include vertical gate lines VGL, horizontal gate lines HGL, and an auxiliary gate line BGL.

The vertical gate lines VGL may be connected (e.g., electrically connected) to a display driver 220 to extend in the second direction (e.g., Y-axis direction) and may be spaced apart from each other in the first direction (e.g., X-axis direction). The vertical gate lines VGL may be disposed in parallel with the data lines DL. The horizontal gate lines HGL may extend in the first direction (e.g., X-axis direction) and may be spaced apart from each other in the second direction (e.g., Y-axis direction). The horizontal gate lines HGL may cross the vertical gate lines VGL. For example, each horizontal gate line HGL may be connected (e.g., electrically connected) to a corresponding one of the vertical gate lines VGL through a contact portion MDC. The contact portion MDC may correspond to a portion in which the horizontal gate line HGL is inserted into the contact hole and contacts the vertical gate lines VGL. An auxiliary gate line BGL may extend from the horizontal gate line HGL to supply gate signals to first to third pixels SP1, SP2, and SP3.

The data lines DL may extend in the second direction (e.g., Y-axis direction) and may be spaced apart from each other in the first direction (e.g., X-axis direction). The data lines DL may include first to third data lines DL1, DL2, and DL3. Each of the first to third data lines DL1, DL2, and DL3 may supply a data voltage to each of the first to third pixels SP1, SP2, and SP3.

The initialization voltage lines VIL may extend in the second direction (e.g., Y-axis direction) and may be spaced apart from each other in the first direction (e.g., X-axis direction). The initialization voltage line VIL may supply the initialization voltage received from the display driver 220 to the pixel circuit PXC of each of the first to third pixels SP1, SP2, and SP3. The initialization voltage line VIL may receive a sensing signal from the pixel circuit PXC of each of the first to third pixels SP1, SP2, and SP3 to supply the sensing signal the display driver 220.

The first voltage lines VDL may extend in the second direction (e.g., Y-axis direction) and may be spaced apart from each other in the first direction (e.g., X-axis direction). The first voltage line VDL may supply a driving voltage or a high potential voltage received from a power supply unit 250 to the first to third pixels SP1, SP2, and SP3.

The horizontal voltage lines HVDL may extend in the first direction (e.g., X-axis direction) and may be spaced apart from each other in the second direction (e.g., Y-axis direction). The horizontal voltage line HVDL may be connected (e.g., electrically connected) to the first voltage line VDL. The horizontal voltage line HVDL may supply a driving voltage or a high potential voltage to the first voltage line VDL.

The vertical voltage lines VVSL may extend in the second direction (e.g., Y-axis direction) and may be spaced apart from each other in the first direction (e.g., X-axis direction). The vertical voltage line VVSL may be connected (e.g., electrically connected) to the second voltage line VSL. The vertical voltage line VVSL may supply the low potential voltage received from the power supply unit 250 to the second voltage line VSL.

The second voltage lines VSL may extend in the first direction (e.g., X-axis direction) and may be spaced apart from each other in the second direction (e.g., Y-axis direction). The second voltage line VSL may supply a low potential voltage. Accordingly, the second voltage line VSL may be a low potential line.

The connection relationship between the pixel SI, the gate lines GL, the data lines DL, the initialization voltage line VIL, the first voltage line VDL, and the second voltage line VSL may be changed or modified according to the number and arrangement of the pixels SP.

The non-display area NDA may be defined as the remaining area of the display panel 100 except for the display area DA. For example, the non-display area NDA may include fan-out lines connecting the vertical gate lines VGL, the data lines DL, the initialization voltage line VIL, the first voltage line VDL, and the vertical voltage line VVSL to the display driver 220, and a pad portion connected (e.g., electrically connected) to the flexible film 210.

Input terminals provided on a side of the flexible film 210 may be attached to the circuit board 230 by a film attaching process, and output terminals provided at another side of the flexible film 210 may be attached to the pad portion by the film attaching process. For example, the flexible film 210 may be bent, such as a tape carrier package or a chip on film. The flexible film 210 may be bent toward the lower portion of the display panel 100 to reduce the bezel area of the display device 10. The display driver 220 may be mounted on the flexible film 210. For example, the display driver 220 may be implemented as an integrated circuit (IC). The display driver 220 may receive digital video data and a data control signal from the timing controller 240, and according to the data control signal, convert the digital video data to an analog data voltage to supply it to the data lines DL through the fan-out lines. The display driver 220 may generate a gate signal according to a gate control signal supplied from the timing controller 240, and sequentially supply the gate signal to the vertical gate lines VGL in a set order. Accordingly, the display driver 220 may simultaneously function as a data driver and a gate driver. Since the display device 10 includes the display driver 220 disposed on the lower side of the non-display area NDA, sizes of the left side, right side, and upper side of the non-display area NDA may be minimized.

A circuit board 230 may support a timing controller 240 and the power supply unit 250, and supply signals and power to the display driver 220. For example, the circuit board 230 may supply a signal supplied from the timing controller 240 and a power voltage supplied from the power supply unit 250 to the display driver 220 to display an image on each pixel. For example, a signal transmission line and a power line may be provided on the circuit board 230.

The timing controller 240 may be mounted on the circuit board 230 and may receive image data and a timing synchronization signal supplied from the display driving system or a graphic device through a user connector provided on the circuit board 230. The timing controller 240 may generate digital video data by arranging the image data to fit the pixel arrangement structure based on the timing synchronization signal, and may supply the generated digital video data to the display driver 220. The timing controller 240 may generate the data control signal and the gate control signal based on the timing synchronization signal. The timing controller 240 may control the data voltage supply timing of the display driver 220 based on the data control signal, and may control the gate signal supply timing of the display driver 220 based on the gate control signal.

The power supply unit 250 may be disposed on the circuit board 230 to supply a power voltage to the display driver 220 and the display panel 100. For example, the power supply unit 250 may generate a driving voltage or a high potential voltage and supply the high potential to the first voltage line VDL, may generate a low potential voltage and supply the low potential voltage to the vertical voltage line VVSL, and may generate an initialization voltage and supply it to the initialization voltage line VIL.

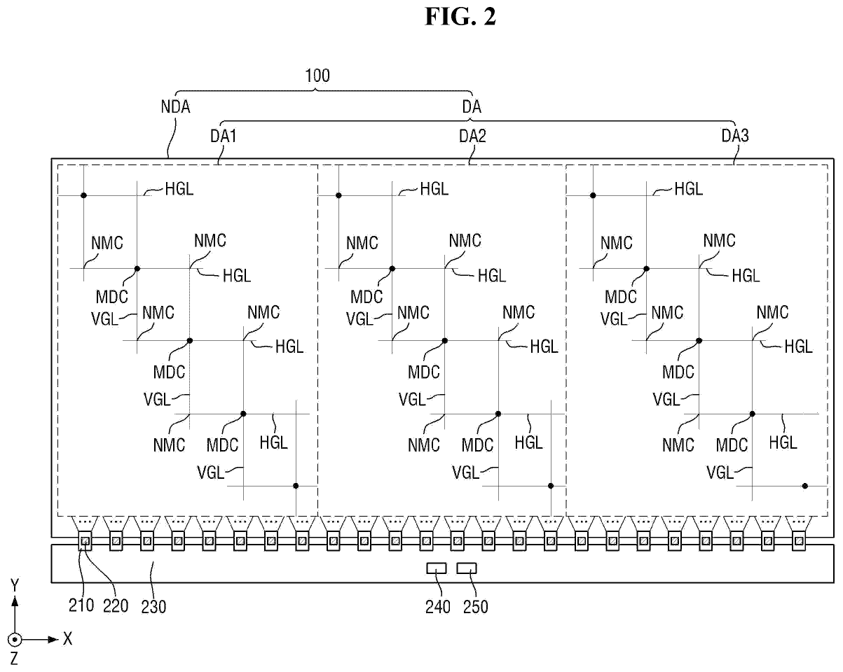

FIG. 2 is a schematic plan view illustrating a contact portion of a vertical gate line and a horizontal gate line in a display device according to an embodiment.

Referring to FIG. 2, the display area DA may include first to third display areas DA1, DA2, and DA3.

Each of the horizontal gate lines HGL may cross the vertical gate lines VGL. The horizontal gate line HGL may cross the vertical gate lines VGL, in the contact portion MDC and a non-contact portion NMC. For example, each horizontal gate line HGL may be connected (e.g., electrically connected) to a corresponding one of the vertical gate lines VGL through a contact portion MDC. Each horizontal gate line HGL may be insulated from the other vertical gate lines VGL in the non-contact portion NMC.

The contact portion MDC of a first display area DA1 may be disposed on an extension line extending from the upper left end portion of the first display area DA1 to the lower right end portion of the first display area DA1. The contact portion MDC of a second display area DA2 may be disposed on an extension line extending from the upper left end portion of the second display area DA2 to the lower right end portion of the second display area DA2. The contact portion MDC of a third display area DA3 may be disposed on an extension line extending from the upper left end portion of the third display area DA3 to the lower right end portion of the third display area DA3. Accordingly, the contact portions MDC may be arranged along a diagonal direction between the opposite directions of the first direction (e.g., X-axis direction) and the second direction (e.g., Y-axis direction) in each of the first to third display areas DA1, DA2, and DA3.

The display device 10 may include the display driver 220 that functions as a data driver and a gate driver. Accordingly, since the data lines DL receives a data voltage from the display driver 220 disposed on the lower side of the non-display area NDA, and the vertical gate lines VGL receives the gate signal from the display driver 220 disposed on the lower side of the non-display area NDA, the display device 10 may minimize the sizes of the left side, right side, and upper side of the non-display area NDA.

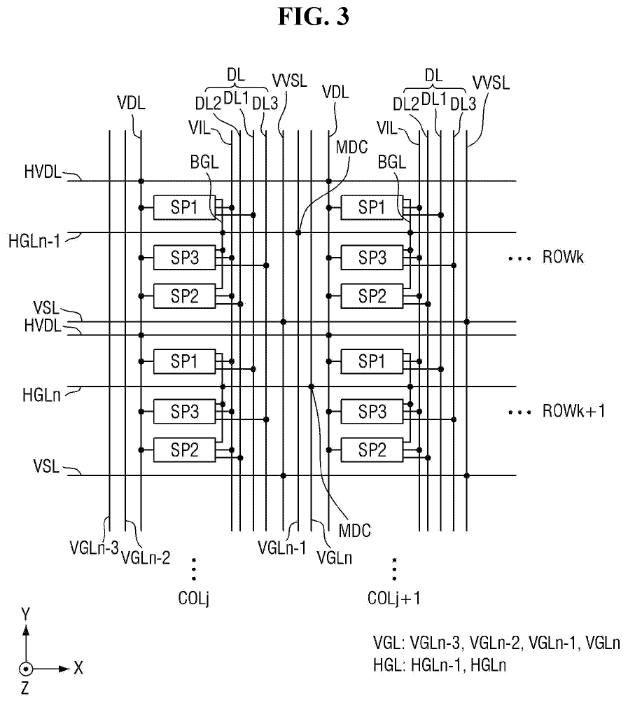

FIG. 3 is a diagram illustrating pixels and lines of a display device according to an embodiment.

Referring to FIG. 3, the pixel SP may include first to third pixels SP1, SP2, and SP3. The pixel circuits PXC of the first pixel SP1, the third pixel SP3 and the second pixel SP2 may be sequentially arranged in the opposite direction of the second direction (e.g., Y-axis direction), but the arrangement direction of the pixel circuits PXC is not limited thereto.

Each of the first to third pixels SP1, SP2, and SP3 may be connected (e.g., electrically connected) to the first voltage line VDL, the initialization voltage line VIL, the gate lines GL, and the data lines DL.

A first voltage line VDL may extend in the second direction (e.g., Y-axis direction). The first voltage line VDL may be disposed on the left side of the pixel circuits PXC of the first to third pixels SP1, SP2, and SP3. The first voltage line VDL may supply a driving voltage or high potential voltage to a transistor of each of the first to third pixels SP1, SP2, and SP3.

The horizontal voltage line HVDL may extend in the first direction (e.g., X-axis direction). The horizontal voltage line HVDL may be disposed on (or adjacent to) the upper side of the pixel circuit PXC of the first pixel SP1. The horizontal voltage line HVDL may be connected (e.g., electrically connected) to the first voltage line VDL. The horizontal voltage line HVDL may supply a driving voltage or a high potential voltage to the first voltage line VDL.

The initialization voltage line VIL may extend in the second direction (e.g., Y-axis direction). The initialization voltage line VIL may be disposed on (or adjacent to) the right side of the auxiliary gate line BGL. The initialization voltage line VIL may be disposed between the auxiliary gate line BGL and the data lines DL. The initialization voltage line VIL may supply an initialization voltage to the pixel circuit PXC of each of the first to third pixels SP1, SP2, and SP3. The initialization voltage line VIL may receive a sensing signal from the pixel circuit PXC of each of the first to third pixels SP1, SP2, and SP3 to supply the sensing signal to the display driver 220.

The gate lines GL may include the vertical gate lines VGL, the horizontal gate line HGL, and an auxiliary gate line BGL.

The vertical gate lines VGL may extend in the second direction (e.g., Y-axis direction). The vertical gate lines VGL may be connected between the display driver 220 and the horizontal gate line HGL. Each of the vertical gate lines VGL may cross the horizontal gate lines HGL. The vertical gate lines VGL may supply the gate signal received from the display driver 220 to the horizontal gate line HGL.

For example, the (n−3)th vertical gate line VGLn−3, where n is a positive integer, and the (n−2)th vertical gate line VGLn−2 may be disposed on (or adjacent to) the left side of the pixel SP disposed in the j^{th} column COLj, where j is a positive integer. The vertical gate lines VGL may be disposed parallel to the left side of the first voltage line VDL. The (n−1)th and n^{th} vertical gate lines VGLn−1 and VGLn may be disposed between the data line DL connected (e.g., electrically connected) to the pixel SP disposed in the j^{th} column COLj and the first voltage line VDL connected (e.g., electrically connected) to the pixel SP disposed in the (j+1)^{th} column COLj+1. The (n−1)^{th} vertical gate line VGLn−1 may be connected (e.g., electrically connected) to the (n−1)^{th} horizontal gate line HGLn−1 through the contact portion MDC, and may be insulated from the remaining horizontal gate lines HGL. The n^{th} vertical gate line VGLn may be connected (e.g., electrically connected) to the n^{th} horizontal gate line HGLn through the contact portion MDC, and may be insulated from the remaining horizontal gate lines HGL. The (n−1)^{th} and n^{th} vertical gate lines VGLn−1 and VGLn may be disposed on (or adjacent to) the left side of the first voltage line VDL connected (e.g., electrically connected) to the pixel SP disposed in the (j+1)^{th} column COLj+1.

The horizontal gate line HGL may extend in a first direction (e.g., X-axis direction). The horizontal gate line HGL may be disposed between the pixel circuit PXC of the first pixel SP1 and the pixel circuit PXC of the third pixel SP3. The horizontal gate line HGL may be disposed below the pixel circuit PXC of the first pixel SP1 and above the pixel circuit PXC of the third pixel SP3. The horizontal gate line HGL may be connected between the vertical gate line VGL and the auxiliary gate line BGL. The horizontal gate line HGL may supply a gate signal received from the vertical gate lines VGL to the auxiliary gate line BGL.

For example, the (n−1)^{th} horizontal gate line HGLn−1 may be disposed on (or adjacent to) the lower side of the pixel circuit PXC of the first pixel SP1 disposed in the kth row ROWk, where k is a positive integer. The (n−1)^{th} horizontal gate line HGLn−1 may be connected (e.g., electrically connected) to the (n−1)^{th} vertical gate line VGLn−1 through the contact portion MDC and may be insulated from the remaining vertical gate lines VGL. The n^{th} horizontal gate line HGLn may be disposed on (or adjacent to) the lower side of the pixel circuit PXC of the first pixel SP1 disposed in the (k+1)^{th} row ROWk+1. The n^{th} horizontal gate line HGLn may be connected (e.g., electrically connected) to the n^{th} vertical gate line VGLn through the contact portion MDC and may be insulated from the remaining vertical gate lines VGL.

The auxiliary gate line BGL may extend from the horizontal gate line HGL in the opposite direction of the second direction (e.g., Y-axis direction). The auxiliary gate line BGL may be disposed on (or adjacent to) the right side of the pixel circuits PXC of the first to third pixels SP1, SP2, and SP3. The auxiliary gate line BGL may supply the gate signals received from the horizontal gate line HGL to the pixel circuits PXC of the first to third pixels SP1, SP2, and SP3.

The data lines DL may extend in the second direction (e.g., Y-axis direction). The data lines DL may supply a data voltage to the pixels SP. The data lines DL may include first to third data lines DL1, DL2, and DL3.

The first data line DL1 may extend in the second direction (e.g., Y-axis direction). The first data line DL1 may be disposed on (or adjacent to) the right side of the second data line DL2. The first data line DL1 may supply the data voltage received from the display driver 220 to the pixel circuit PXC of the first pixel SP1.

The second data line DL2 may extend in the second direction (e.g., Y-axis direction). The second data line DL2 may be disposed on (or adjacent to) the right side of the initialization voltage line VIL. The second data line DL2 may supply the data voltage received from the display driver 220 to the pixel circuit PXC of the second pixel SP2.

The third data line DL3 may extend in the second direction (e.g., Y-axis direction). The third data line DL3 may be disposed on (or adjacent to) the right side of the first data line DL1. The third data line DL3 may supply the data voltage received from the display driver 220 to the pixel circuit PXC of the third pixel SP3.

The vertical voltage line VVSL may extend in the second direction (e.g., Y-axis direction). The vertical voltage line VVSL may be disposed on (or adjacent to) the right side of the third data line DL3. The vertical voltage line VVSL may be connected between the power supply unit 250 and the second voltage line VSL. The vertical voltage line VVSL may supply the low potential voltage supplied from the power supply unit 250 to the second voltage line VSL.

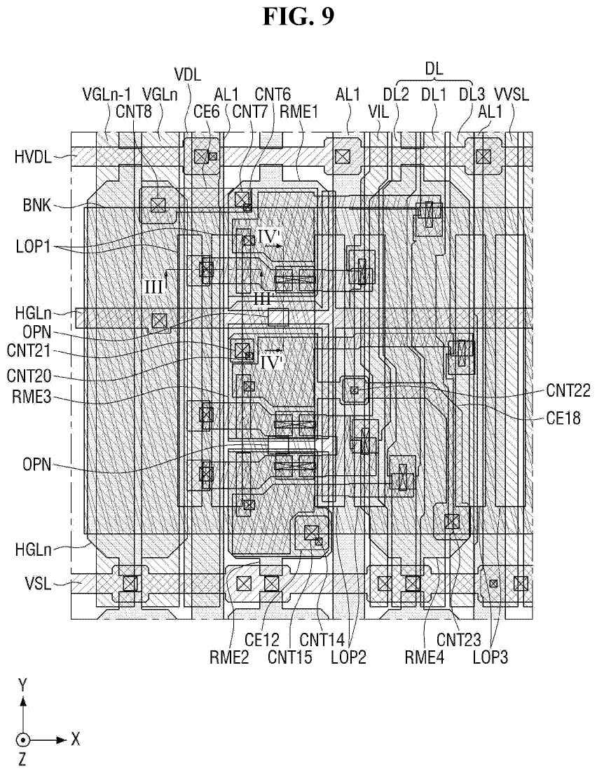

The second voltage line VSL may extend in the first direction (e.g., X-axis direction). The second voltage line VSL may be disposed on (or adjacent to) the lower side of the pixel circuit PXC of the second pixel SP2. The second voltage line VSL may supply the low potential voltage received from the vertical voltage line VVSL to a light emitting element layer of the first to third pixels SP1, SP2, and SP3. The light emitting element layers of the first to third pixels SP1, SP2, and SP3 will be described in detail with reference to FIGS. 9 to 15.

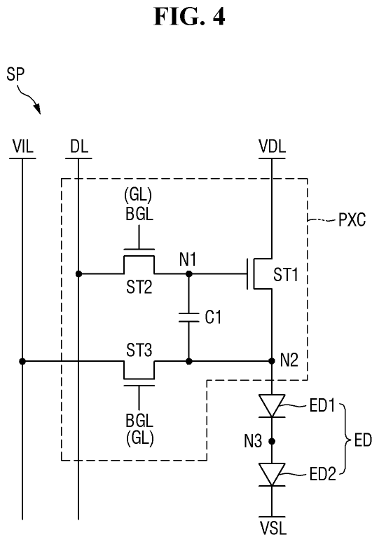

FIG. 4 is a schematic diagram of an equivalent circuit of a pixel of a display device according to an embodiment.

Referring to FIG. 4, each of the pixels SP may be connected (e.g., electrically connected) to the first voltage line VDL, the data line DL, the initialization voltage line VIL, the gate lines GL, and the second voltage line VSL.

Each of the first to third pixels SP1, SP2, and SP3 may include first to third transistors ST1, ST2, and ST3, a first capacitor C1, and light emitting elements ED.

The first transistor ST1 may include a gate electrode, a drain electrode, and a source electrode. The gate electrode of the first transistor ST1 may be connected (e.g., electrically connected) to a first node N1, the drain electrode thereof may be connected (e.g., electrically connected) to the first voltage line VDL, and the source electrode thereof may be connected (e.g., electrically connected) to a second node N2. The first transistor ST1 may control a drain-source current (or driving current) based on a data voltage applied to the gate electrode thereof.

The light emitting elements ED may include a first light emitting element ED1 and a second light emitting element ED2. The first and second light emitting elements ED1 and ED2 may be connected in series. The first and second light emitting elements ED1 and ED2 may receive a driving current to emit light. The light emission amount or the luminance of the light emitting element ED may be proportional to the magnitude of the driving current. The light emitting element ED may be an inorganic light emitting element including an inorganic semiconductor, but embodiments are not limited thereto.

The first electrode of the first light emitting element ED1 may be connected (e.g., electrically connected) to the second node N2, and the second electrode of the first light emitting element ED1 may be connected (e.g., electrically connected) to a third node N3. The first electrode of the first light emitting element ED1 may be connected (e.g., electrically connected) to the source electrode of the first transistor ST1, the drain electrode of the third transistor ST3 and a second capacitor electrode of the first capacitor C1 through the second node N2. The second electrode of the first light emitting element ED1 may be connected (e.g., electrically connected) to the first electrode of the second light emitting element ED2 through the third node N3.

The first electrode of the second light emitting element ED2 may be connected (e.g., electrically connected) to the third node N3 and the second electrode of the second light emitting element ED2 may be connected (e.g., electrically connected) to the second voltage line VSL. The second electrode of the second light emitting element ED2 may receive a low potential voltage from the second voltage line VSL.

The second transistor ST2 may be turned on by the gate signal of the gate line GL to connect the data line DL to the first node N1 which is the gate electrode of the first transistor ST1. The second transistor ST2 may be turned on according to the gate signal to supply the data voltage to the first node N1. The gate electrode of the second transistor ST2 may be connected (e.g., electrically connected) to the gate line GL, the drain electrode thereof may be connected (e.g., electrically connected) to the data line DL, and the source electrode thereof may be connected (e.g., electrically connected) to the first node N1. The source electrode of the second transistor ST2 may be connected (e.g., electrically connected) to the gate electrode of the first transistor ST1 and a first capacitor electrode of the first capacitor C1 through the first node N1.

The third transistor ST3 may be turned on by the gate signal of the gate line GL to connect the initialization voltage line VIL to the second node N2 that is the source electrode of the first transistor ST1. The third transistor ST3 may be turned on according to the gate signal to supply the initialization voltage to the second node N2. The third transistor ST3 may be turned on according to the gate signal to supply the sensing signal to the initialization voltage line VIL. The gate electrode of the third transistor ST3 may be connected (e.g., electrically connected) to the gate line GL, the drain electrode thereof may be connected (e.g., electrically connected) to the second node N2, and the source electrode thereof may be connected (e.g., electrically connected) to the initialization voltage line VIL. The drain electrode of the third transistor ST3 may be connected (e.g., electrically connected) to the source electrode of the first transistor ST1, the second capacitor electrode of the first capacitor C1 and the first electrode of the first light emitting element ED1 through the second node N2.

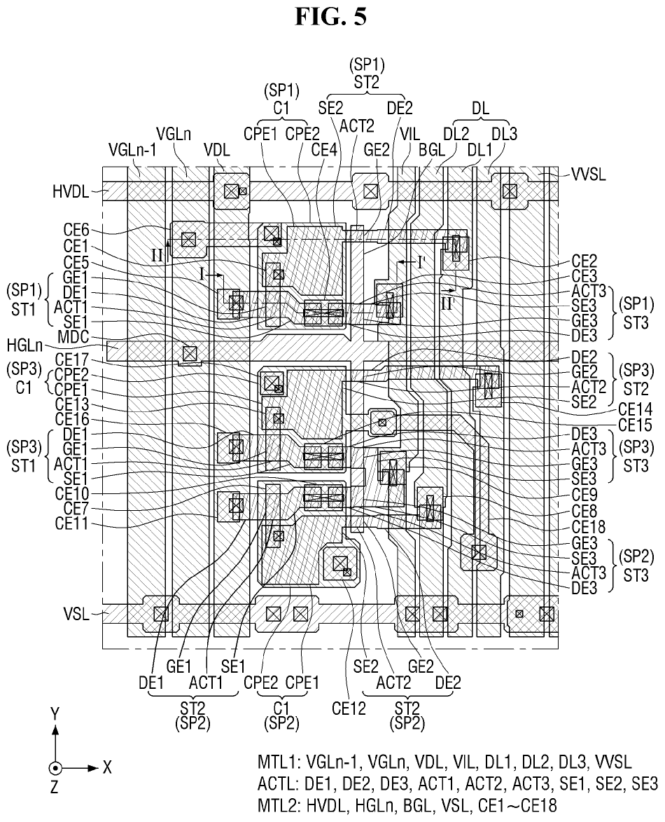

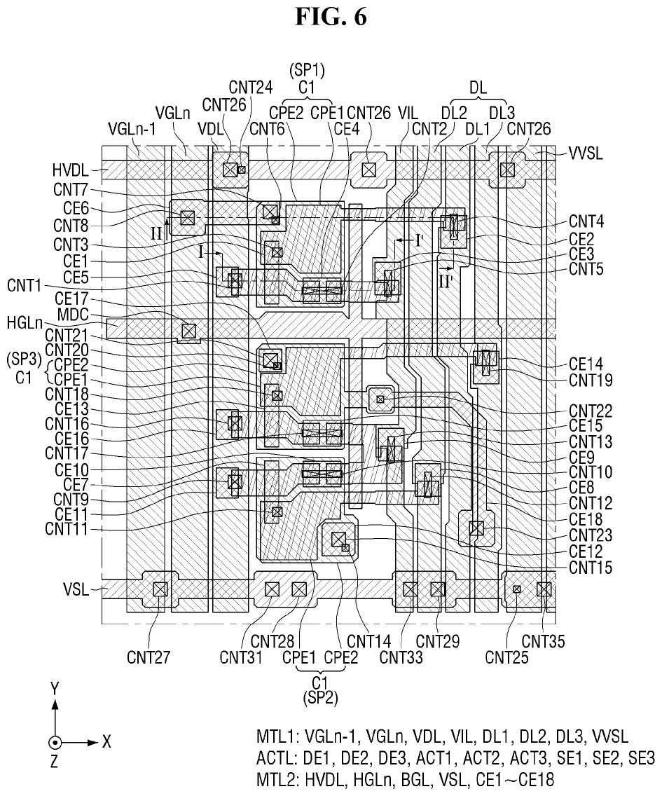

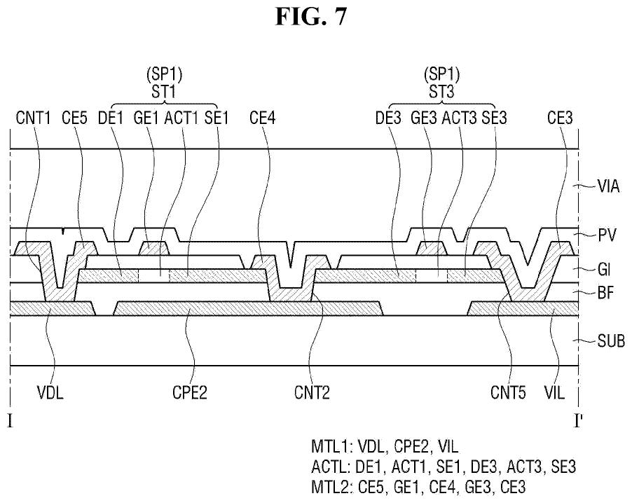

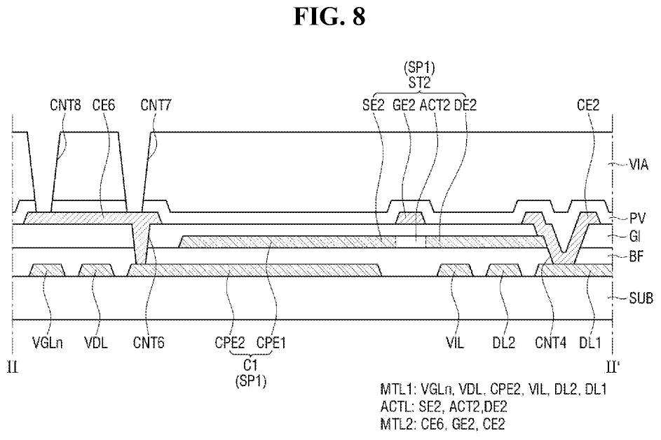

FIGS. 5 and 6 are schematic plan views illustrating a portion of a display area in a display device according to an embodiment. FIGS. 5 and 6 illustrate by dividing the reference numerals of the same view. FIG. 7 is a schematic cross-sectional view taken along line I-I′ of FIGS. 5 and 6 and FIG. 8 is a schematic cross-sectional view taken along line II-II′ of FIGS. 5 and 6.

Referring to FIGS. 5 to 8, the display area DA may include the pixels SP, the first voltage line VDL, the horizontal voltage line HVDL, the initialization voltage line VIL, the (n−1)^{th} vertical gate line VGLn−1, the n^{th} vertical gate line VGLn, the n^{th} horizontal gate line HGLn, the auxiliary gate line BGL, the data lines DL, the vertical voltage line VVSL, and the second voltage line VSL.

The pixels SP may include first to third pixels SP1, SP2, and SP3. The pixel circuits PXC of the first pixel SP1, the third pixel SP3 and the second pixel SP2 may be sequentially arranged in the opposite direction of the second direction (e.g., Y-axis direction). The pixel circuit PXC of each of the first to third pixels SP1, SP2, and SP3 may be disposed in the pixel area.

The first voltage line VDL may be disposed in (or formed of) a first metal layer MTL1 on the substrate SUB. The first voltage line VDL may be disposed to (or adjacent to) the left side of the pixel circuits PXC of the first to third pixels SP1, SP2 and SP3. A fifth connection electrode CE5 of the second metal layer MTL2 may connect (e.g., electrically connect) the first voltage line VDL and the drain electrode DE1 of the first transistor ST1 of the first pixel SP1 through a first contact hole CNT1. An eleventh connection electrode CE11 of the second metal layer MTL2 may connect (e.g., electrically connect) the first voltage line VDL and the drain electrode DE1 of the first transistor ST1 of the second pixel SP2 through a ninth contact hole CNT9. A sixteenth connection electrode CE16 of the second metal layer MTL2 may connect (e.g., electrically connect) the first voltage line VDL and the drain electrode DE1 of the first transistor ST1 of the third pixel SP3 through a sixteenth contact hole CNT16. Accordingly, the first voltage line VDL may supply a driving voltage or a high potential voltage to the first to third pixels SP1, SP2, and SP3.

The horizontal voltage line HVDL may be disposed in (or formed of) the second metal layer MTL2. The second metal layer MTL2 may be disposed on a gate insulating layer GI covering an active layer ACTL. The horizontal voltage line HVDL may be disposed on (or adjacent to) the upper side of the pixel circuit PXC of the first pixel SP1. The horizontal voltage line HVDL may be connected (e.g., electrically connected) to the first voltage line VDL through a twenty-fourth contact hole CNT24 to supply a driving voltage or a high potential voltage. The horizontal voltage line HVDL may supply a first alignment signal to a first alignment line AL1. Here, the first alignment line AL1 may be disposed in (or formed of) a third metal layer MTL3 on the second metal layer MTL2 and twenty-sixth contact holes CNT26 may be formed penetrating a via layer VIA and a passivation layer PV. The first alignment line AL1 and the third metal layer MTL3 will be described in detail with reference to FIGS. 9 to 15. The passivation layer PV may be disposed on the second metal layer MTL2 and the gate insulating layer GI, and the via layer VIA may be disposed on the passivation layer PV.

The initialization voltage line VIL may be disposed in (or formed of) the first metal layer MTL1. The initialization voltage line VIL may be disposed on (or adjacent to) the right side of the auxiliary gate line BGL. A third connection electrode CE3 of the second metal layer MTL2 may connect (e.g., electrically connect) the initialization voltage line VIL to the source electrode SE3 of the third transistor ST3 of the first pixel SP1 through the fifth contact hole CNT5. A ninth connection electrode CE9 of the second metal layer MTL2 may connect (e.g., electrically connect) the initialization voltage line VIL to the source electrode SE3 of the third transistor ST3 of the second pixel SP2 through a thirteenth contact hole CNT13. The ninth connection electrode CE9 may connect (e.g., electrically connect) the initialization voltage line VIL to the source electrode SE3 of the third transistor ST3 of the third pixel SP3 through the thirteenth contact hole CNT13. The source electrode SE3 of the third transistor ST3 of the second pixel SP2 and the source electrode SE3 of the third transistor ST3 of the third pixel SP3 may be integral with each other, but embodiments are not limited thereto. Accordingly, the initialization voltage line VIL may supply the initialization voltage to the third transistor ST3 of each of the first to third pixels SP1, SP2, and SP3 and receive the sensing signal from the third transistor ST3.

The vertical gate lines VGL may be disposed in (or formed of) the first metal layer MTL1. The (n−1)^{th} and n^{th} vertical gate lines VGLn−1 and VGLn may be disposed on (or adjacent to) the left side of the first voltage line VDL. The n^{th} vertical gate line VGLn may be connected (e.g., electrically connected) to the n^{th} horizontal gate line HGLn of the second metal layer MTL2 through the contact portion MDC. The n^{th} vertical gate line VGLn may supply a gate signal to the n^{th} horizontal gate line HGLn.

The n^{th} horizontal gate line HGLn may be disposed in (or formed of) the second metal layer MTL2. The n^{th} horizontal gate line HGLn may be disposed between the pixel circuit PXC of the first pixel SP1 and the pixel circuit PXC of the third pixel SP3. The pixel circuit PXC of the first pixel SP1 and the pixel circuit PXC of the third pixel SP3 may be spaced apart by the thickness of the n^{th} horizontal gate line HGLn. The n^{th} horizontal gate line HGLn may be connected (e.g., electrically connected) to the n^{th} vertical gate line VGLn disposed in (or formed of) the first metal layer MTL1 through the contact portion MDC. The n^{th} horizontal gate line HGLn may supply a gate signal received from the n^{th} vertical gate line VGLn to the auxiliary gate line BGL.

The auxiliary gate line BGL may be disposed in (or formed of) the second metal layer MTL2. A first portion of the auxiliary gate line BGL may protrude in the second direction (e.g., Y-axis direction) from the n^{th} horizontal gate line HGLn, and a second portion of the auxiliary gate line BGL may protrude in a direction opposite to the second direction (e.g., Y-axis direction) from the n^{th} horizontal gate line. The auxiliary gate line BGL may be integral with the n^{th} horizontal gate line HGLn, but embodiments are not limited thereto. The first portion of the auxiliary gate line BGL may be disposed on (or adjacent to) the right side of the pixel circuit PXC of the first pixel SP1, and the second portion of the auxiliary gate line BGL may be disposed on (or adjacent to) the right side of the pixel circuits PXC of the second and third pixels SP2 and SP3. The auxiliary gate line BGL may supply the gate signal received from the n^{th} horizontal gate line HGLn to the second and third transistors ST2 and ST3 of the first to third pixels SP1, SP2, and SP3, respectively.

The first data line DL1 may be disposed in (or formed of) the first metal layer MTL1. The first data line DL1 may be disposed on (or adjacent to) the right side of the second data line DL2. The second connection electrode CE2 of the second metal layer MTL2 may connect (e.g., electrically connect) the first data line DL1 to a drain electrode DE2 of the second transistor ST2 of the first pixel SP1 through a fourth contact hole CNT4. The first data line DL1 may supply a data voltage to the second transistor ST2 of the first pixel SP1.

The second data line DL2 may be disposed in (or formed of) the first metal layer MTL1. The second data line DL2 may be disposed on (or adjacent to) the right side of the initialization voltage line VIL. An eighth connection electrode CE8 of the second metal layer MTL2 may connect (e.g., electrically connect) the second data line DL2 to the drain electrode DE2 of the second transistor ST2 of the second pixel SP2 through the twelfth contact hole CNT12. The second data line DL2 may supply a data voltage to the second transistor ST2 of the second pixel SP2.

The third data line DL3 may be disposed in (or formed of) the first metal layer MTL1. The third data line DL3 may be disposed on (or adjacent to) the right side of the first data line DL1. A fourteenth connection electrode CE14 of the second metal layer MTL2 may connect (e.g., electrically connect) the third data line DL3 to the drain electrode DE2 of the second transistor ST2 of the third pixel SP3 through a nineteenth contact hole CNT19. The third data line DL3 may supply a data voltage to the second transistor ST2 of the third pixel SP3.

The vertical voltage line VVSL may be disposed in (or formed of) the first metal layer MTL1. The vertical voltage line VVSL may be disposed on (or adjacent to) the right side of the third data line DL3. The vertical voltage line VVSL may be connected (e.g., electrically connected) to the second voltage line VSL of the second metal layer MTL2 through a twenty-fifth contact hole CNT25. The vertical voltage line VVSL may supply a low potential voltage to the second voltage line VSL.

The second voltage line VSL may be disposed in (or formed of) the second metal layer MTL2. The second voltage line VSL may be disposed on (or adjacent to) the lower side of the pixel circuit PXC of the second pixel SP2. The second voltage line VSL may supply the low potential voltage received from the vertical voltage line VVSL to each of the first to third pixels SP1, SP2, and SP3. For example, the second voltage line VSL may be connected (e.g., electrically connected) to the contact electrodes CTE1, CTE2, and CTE3 of the first pixel SP1 through a thirty-first contact hole CNT31. The second voltage line VSL may be connected (e.g., electrically connected) to the contact electrodes CTE1, CTE2, and CTE3 of the second pixel SP2 through a thirty-third contact hole CNT33. The second voltage line VSL may be connected (e.g., electrically connected) to the contact electrodes CTE1, CTE2, and CTE3 of the third pixel SP3 through a thirty-fifth contact hole CNT35. For example, the contact electrodes CTE1, CTE2, and CTE3 may be disposed in (or formed of) a fourth metal layer MTL4 on the third metal layer MTL3. The fourth metal layer MTL4 will be described in detail with reference to FIGS. 9 to 15.

The second voltage line VSL may supply a second alignment signal to a second alignment line AL2 of the third metal layer MTL3. For example, the second voltage line VSL may be connected (e.g., electrically connected) to a second alignment line AL2 of the first pixel SP1 through a twenty-seventh contact hole CNT27. The second voltage line VSL may be connected (e.g., electrically connected) to a second alignment line AL2 of the second pixel SP2 through a twenty-eighth contact hole CNT28. The second voltage line VSL may be connected (e.g., electrically connected) to a second alignment line AL2 of the third pixel SP3 through a twenty-ninth contact hole CNT29. Here, the second alignment line AL2 may be disposed in (or formed of) the third metal layer MTL3, and the twenty-seventh to twenty-ninth contact holes CNT27, CNT28, and CNT29 may be formed penetrating the via layer VIA and the passivation layer PV. The second alignment line AL2 will be described in detail with reference to FIGS. 9 to 15.

The pixel circuit PXC of the first pixel SP1 may include first to third transistors ST1, ST2, and ST3 and the first capacitor C1. The first transistor ST1 of the first pixel SP1 may include an active region ACT1, a gate electrode GE1, a drain electrode DE1, and a source electrode SE1. The active region ACT1 of the first transistor ST1 may be disposed in (or formed of) the active layer ACTL and may overlap the gate electrode GE1 of the first transistor ST1 in the thickness direction (e.g., Z-axis direction). The active layer ACTL may be disposed on a buffer layer BF covering the first metal layer MTL1.

The gate electrode GE1 of the first transistor ST1 may be disposed in (or formed of) the second metal layer MTL2. The gate electrode GE1 of the first transistor ST1 may be integral with a first connection electrode CE1. The first connection electrode CE1 may be connected (e.g., electrically connected) to a first capacitor electrode CPE1 of the first capacitor C1 disposed in (or formed of) the active layer ACTT, through a third contact hole CNT3. The first capacitor electrode CPE of the first capacitor C1 may be made conductive by heat treatment of the active layer ACTL. The first capacitor electrode CPE1 of the first capacitor C1 may be integral with a source electrode SE2 of the second transistor ST2, but embodiments are not limited thereto.

The drain electrode DE1 and the source electrode SE1 of the first transistor ST1 may be made conductive by heat treatment of the active layer ACTL. The drain electrode DE1 and the source electrode SE1 may be formed into an N-type semiconductor, but embodiments are not limited thereto. The fifth connection electrode CE5 may connect (e.g., electrically connect) the first voltage line VDL to the drain electrode DE1 of the first transistor ST1 of the first pixel SP1 through the first contact hole CNT1. The drain electrode DE1 of the first transistor ST1 may receive a driving voltage or a high potential voltage from the first voltage line VDL.

A fourth connection electrode CE4 of the second metal layer MTL2 may connect (e.g., electrically connect) the source electrode SE1 of the first transistor ST1, a drain electrode DE3 of the third transistor ST3 and a second capacitor electrode CPE2 of the first metal layer MTL1 through a second contact hole CNT2. The first capacitor C1 may be formed between the first capacitor electrode CPE1 of the active layer ACTL and the second capacitor electrode CPE2 of the first metal layer MTL1.

A sixth connection electrode CE6 of the second metal layer MTL2 may be connected (e.g., electrically connected) to the second capacitor electrode CPE2 through a sixth contact hole CNT6. The sixth connection electrode CE6 may be connected (e.g., electrically connected) to the first electrode of the third metal layer MTL3 through a seventh contact hole CNT7, and may be connected (e.g., electrically connected) to the fifth electrode of the third metal layer MTL3 through an eighth contact hole CNT8. The first electrode and the fifth electrode of the third metal layer MTL3 will be described in detail with reference to FIGS. 9 to 15.

The second transistor ST2 of the first pixel SP1 may include an active region ACT2, a gate electrode GE2, a drain electrode DE2, and a source electrode SE2. The active region ACT2 of the second transistor ST2 may be disposed in (or formed of) the active layer ACTL and may overlap the gate electrode GE2 of the second transistor ST2 in the thickness direction (e.g., Z-axis direction).

The gate electrode GE2 of the second transistor ST2 may be disposed in (or formed of) the second metal layer MTL2. The gate electrode GE2 of the second transistor ST2 may be a part of the auxiliary gate line BGL.

The drain electrode DE2 and the source electrode SE2 of the second transistor ST2 may be made conductive by heat treatment of the active layer ACTL. The second connection electrode CE2 may connect (e.g., electrically connect) the drain electrode DE2 of the second transistor ST2 to the first data line DL1 through the fourth contact hole CNT4. The drain electrode DE2 of the second transistor ST2 may receive the data voltage of the first pixel SP1 from the first data line DL1.

The source electrode SE2 of the second transistor ST2 may be integral with the first capacitor electrode CPE1 of the first capacitor C1. The source electrode SE2 of the second transistor ST2 may be connected (e.g., electrically connected) to the gate electrode GE1 of the first transistor ST1 through the first capacitor electrode CPE1 and the first connection electrode CE1.

The third transistor ST3 of the first pixel SP1 may include an active region ACT3, a gate electrode GE3, a drain electrode DE3, and a source electrode SE3. The active region ACT3 of the third transistor ST3 may be disposed in (or formed of) the active layer ACTL and may overlap the gate electrode GE3 of the third transistor ST3 in the thickness direction (e.g., Z-axis direction).

The gate electrode GE3 of the third transistor ST3 may be disposed in (or formed of) the second metal layer MTL2. The gate electrode GE3 of the third transistor ST3 may be a part of the auxiliary gate line BGL.

The drain electrode DE3 and the source electrode SE3 of the third transistor ST3 may be made conductive by heat treatment of the active layer ACTL. The drain electrode DE3 of the third transistor ST3 may be connected (e.g., electrically connected) to the source electrode SE1 of the first transistor ST1 and the second capacitor electrode CPE2 through the fourth connection electrode CE4.

The source electrode SE3 of the third transistor ST3 may be connected (e.g., electrically connected) to the third connection electrode CE3 of the second metal layer MTL2 through the fifth contact hole CNT5. The third connection electrode CE3 may connect (e.g., electrically connect) the source electrode SE3 of the third transistor ST3 to the initialization voltage line VIL. The source electrode SE3 of the third transistor ST3 may receive the initialization voltage from the initialization voltage line VIL. The source electrode SE3 of the third transistor ST3 may supply a sensing signal to the initialization voltage line VIL.

The pixel circuit PXC of the second pixel SP2 may include first to third transistors ST1, ST2, and ST3 and the first capacitor C1. The first transistor ST1 of the second pixel SP2 may include an active region ACT1, a gate electrode GE1, a drain electrode DE1, and a source electrode SE1. The active region ACT1 of the first transistor ST1 may be disposed in (or formed of) the active layer ACTL and may overlap the gate electrode GE1 of the first transistor ST1 in the thickness direction (e.g., Z-axis direction).

The gate electrode GE1 of the first transistor ST1 may be disposed in (or formed of) the second metal layer MTL2. The gate electrode GE1 of the first transistor ST1 may be integral with a seventh connection electrode CET. The seventh connection electrode CE7 may be connected (e.g., electrically connected) to the first capacitor electrode CPE1 of the first capacitor C1 disposed in (or formed of) the active layer ACTL through an eleventh contact hole CNT11. The first capacitor electrode CPE1 of the first capacitor C1 may be made conductive by heat treatment of the active layer ACTL. The first capacitor electrode CPE1 of the first capacitor C1 may be integral with the source electrode SE2 of the second transistor ST2, but embodiments are not limited thereto.

The drain electrode DE1 and the source electrode SE1 of the first transistor ST1 may be made conductive by heat treatment of the active layer. The drain electrode DE1 and the source electrode SE1 may be formed into an N-type semiconductor, but embodiments are not limited thereto. The eleventh connection electrode CE11 may connect (e.g., electrically connect) the first voltage line VDL to the drain electrode DE1 of the first transistor ST1 of the second pixel SP2 through the ninth contact hole CNT9. The drain electrode DE1 of the first transistor ST1 may receive a driving voltage or a high potential voltage from the first voltage line VDL.

A tenth connection electrode CE10 of the second metal layer MTL2 may connect electrically connect) the source electrode SE1 of the first transistor ST1, the drain electrode DE3 of the third transistor ST3 and the second capacitor electrode CPE2 of the first metal layer MTL1 through a tenth contact hole CNT10. The first capacitor C1 may be formed between the first capacitor electrode CPE1 of the active layer ACTL and the second capacitor electrode CPE2 of the first metal layer MTL1.

A twelfth connection electrode CE12 of the second metal layer MTL2 may be connected (e.g., electrically connected) to the second capacitor electrode CPE2 through a fourteenth contact hole CNT14. The twelfth connection electrode CE12 may be connected (e.g., electrically connected) to the second electrode of the third metal layer MTL3 through a fifteenth contact hole CNT15. The second electrode of the third metal layer MTL3 will be described in detail with reference to FIGS. 9 to 15.

The second transistor ST2 of the second pixel SP2 may include an active region ACT2, a gate electrode GE2, a drain electrode DE2, and a source electrode SE2. The active region ACT2 of the second transistor ST2 may be disposed in (or formed of the active layer ACM and may overlap the gate electrode GE2 of the second transistor ST2 in the thickness direction (e.g., Z-axis direction).

The gate electrode GE2 of the second transistor ST2 may be disposed in (or formed of) the second metal layer MTL2. The gate electrode GE2 of the second transistor ST2 may be a part of the auxiliary gate line BGL.

The drain electrode DE2 and the source electrode SE2 of the second transistor ST2 may be made conductive by heat treatment of the active layer ACTL. The eighth connection electrode CE8 may connect (e.g., electrically connect) the drain electrode DE2 of the second transistor ST2 and the second data line DL2 through the twelfth contact hole CNT12. The drain electrode DE2 of the second transistor ST2 may receive the data voltage of the second pixel SP2 from the second data line DL2.

The source electrode SE2 of the second transistor ST2 may be integral with the first capacitor electrode CPE1 of the first capacitor C1. The source electrode SE2 of the second transistor ST2 may be connected (e.g., electrically connected) to the gate electrode GE1 of the first transistor ST1 through the first capacitor electrode CPE1 and the seventh connection electrode CET

The third transistor ST3 of the second pixel SP2 may include the active region ACT3, the gate electrode GE3, the drain electrode DE3, and the source electrode SE3. The active region ACT3 of the third transistor ST3 may be disposed in (or formed of) the active layer ACM and may overlap the gate electrode GE3 of the third transistor ST3 in the thickness direction (e.g., Z-axis direction).

The gate electrode GE3 of the third transistor ST3 may be disposed in (or formed of) the second metal layer MTL2. The gate electrode GE3 of the third transistor ST3 may be a part of the auxiliary gate line BGL.

The drain electrode DE3 and the source electrode SE3 of the third transistor ST3 may be made conductive by heat treatment of the active layer ACTL. The drain electrode DE3 of the third transistor ST3 may be connected (e.g., electrically connected) to the source electrode SE1 and the second capacitor electrode CPE2 of the first transistor ST1.

The source electrode SE3 of the third transistor ST3 may be connected (e.g., electrically connected) to the ninth connection electrode CE9 of the second metal layer MTL2 through the thirteenth contact hole CNT13. The ninth connection electrode CE9 may connect (e.g., electrically connect) the source electrode SE3 of the third transistor ST3 to the initialization voltage line VIL. The source electrode SE3 of the third transistor ST3 may receive the initialization voltage from the initialization voltage line VIL. The source electrode SE3 of the third transistor ST3 may supply a sensing signal to the initialization voltage line VIL.

The pixel circuit PXC of the third pixel SP3 may include first to third transistors ST1, ST2, and ST3 and a first capacitor C1. The first transistor ST1 of the third pixel SP3 may include the active region ACT1, the gate electrode GE1 the drain electrode DE1, and the source electrode SE1. The active region ACT1 of the first transistor ST1 may be disposed in (or formed of) the active layer ACTL and may overlap the gate electrode GE1 of the first transistor ST1 in the thickness direction (e.g., Z-axis direction).

The gate electrode GE1 of the first transistor ST1 may be disposed in (or formed of) the second metal layer MTL2. The gate electrode GE1 of the first transistor ST1 may be integral with a thirteenth connection electrode CE13. The thirteenth connection electrode CE13 may be connected (e.g., electrically connected) to the first capacitor electrode CPE1 of the first capacitor C1 disposed in (or formed of) the active layer ACM through an eighteenth contact hole CNT18. The first capacitor electrode CPE1 of the first capacitor C1 may be made conductive by heat treatment of the active layer ACTL. The first capacitor electrode CPE1 of the first capacitor C1 may be integral with the source electrode SE2 of the second transistor ST2, but embodiments are not limited thereto.

The drain electrode DE1 and the source electrode SE1 of the first transistor ST1 may be made conductive by heat treatment of the active layer ACTL. The drain electrode DE1 and the source electrode SE1 may be made of an IN-type semiconductor, hut embodiments are not limited thereto. The sixteenth connection electrode CE16 may connect (e.g., electrically connect) the first voltage line VDL and the drain electrode DE1 of the first transistor ST1 of the third pixel SP3 through the sixteenth contact hole CNT16. The drain electrode DEL of the first transistor ST1 may receive a driving voltage or a high potential voltage from the first voltage line VDL.

A fifteenth connection electrode CE15 of the second metal layer may connect (e.g., electrically connect) the source electrode SE1 of the first transistor ST1, the drain electrode DE3 of the third transistor ST3, and the second capacitor electrode CPE2 of the first metal layer MTL1 through a seventeenth contact hole CNT17. The first capacitor C1 may be formed between the first capacitor electrode CPE1 of the active layer ACTL and the second capacitor electrode CPE2 of the first metal layer MTL1.

A seventeenth connection electrode CE17 of the second metal layer MTL2 may be connected (e.g., electrically connected) to the second capacitor electrode CPE2 through a twentieth contact hole CNT20. A seventeenth connection electrode CE17 may be connected (e.g., electrically connected) to the third electrode of the third metal layer MTL3 through a twenty-first contact hole CNT21. The third electrode of the third metal layer MTL3 will be described in detail with reference to FIGS. 9 to 15.

An eighteenth connection electrode CE18 of the second metal layer MTL2 may be connected (e.g., electrically connected) to the second capacitor electrode CPE2 through a twenty-second contact hole CNT22. The eighteenth connection electrode CE18 may be connected (e.g., electrically connected) to the fourth electrode of the third metal layer MTL3 through a twenty-third contact hole CNT23. The fourth electrode of the third metal layer MTL3 will be described in detail with reference to FIGS. 9 to 15.

The second transistor ST2 of the third pixel SP3 may include the active region ACT2, the gate electrode GE2, the drain electrode DE2, and the source electrode SE2. The active region ACT2 of the second transistor ST2 may be disposed in (or formed of) the active layer ACTL and may overlap the gate electrode GE2 of the second transistor ST2 in the thickness direction (e.g., Z-axis direction).

The gate electrode GE2 of the second transistor ST2 may be disposed in (or formed of) the second metal layer MTL2. The gate electrode GE2 of the second transistor ST2 may be a part of the auxiliary gate line BGL.

The drain electrode DE2 and the source electrode SE2 of the second transistor ST2 may be made conductive by heat treatment of the active layer ACTL. The fourteenth connection electrode CE14 may connect (e.g., electrically connect) the drain electrode DE2 of the second transistor ST2 and the third data line DE3 through the nineteenth contact hole CNT19. The drain electrode DE2 of the second transistor ST2 may receive the data voltage of the third pixel SP3 from the third data line DL3.

The source electrode SE2 of the second transistor ST2 may be integral with the first capacitor electrode CPE1 of the first capacitor C1. The source electrode SE2 of the second transistor ST2 may be connected (e.g., electrically connected) to the gate electrode GE1 of the first transistor ST1 through the first capacitor electrode CPE1 and the thirteenth connection electrode CE13.

The third transistor ST3 of the third pixel SP3 may include the active region ACT3, the gate electrode GE3, the drain electrode DE3, and the source electrode SE3. The active region ACT3 of the third transistor ST3 may be disposed in (or formed of) the active layer ACTL and may overlap the gate electrode GE3 of the third transistor ST3 in the thickness direction (e.g., Z-axis direction).

The gate electrode GE3 of the third transistor ST3 may be disposed in (or formed of) the second metal layer MTL2. The gate electrode GE3 of the third transistor ST3 may be a part of the auxiliary gate line BGL.

The drain electrode DE3 and the source electrode SE3 of the third transistor ST3 may be made conductive by heat treatment of the active layer ACTL. The drain electrode DE3 of the third transistor ST3 may be connected (e.g., electrically connected) to the source electrode SE1 of the first transistor ST1 and the second capacitor electrode CPE2 through the fifteenth connection electrode CE15.

The source electrode SE3 of the third transistor ST3 may be connected (e.g., electrically connected) to the ninth connection electrode CE9 through the thirteenth contact hole CNT13. The ninth connection electrode CE9 may connect (e.g., electrically connect) the source electrode SE3 of the third transistor ST3 to the initialization voltage line VIL. The source electrode SE3 of the third transistor ST3 may receive the initialization voltage from the initialization voltage line VIL. The source electrode SE3 of the third transistor ST3 may supply a sensing signal to the initialization voltage line VIL.

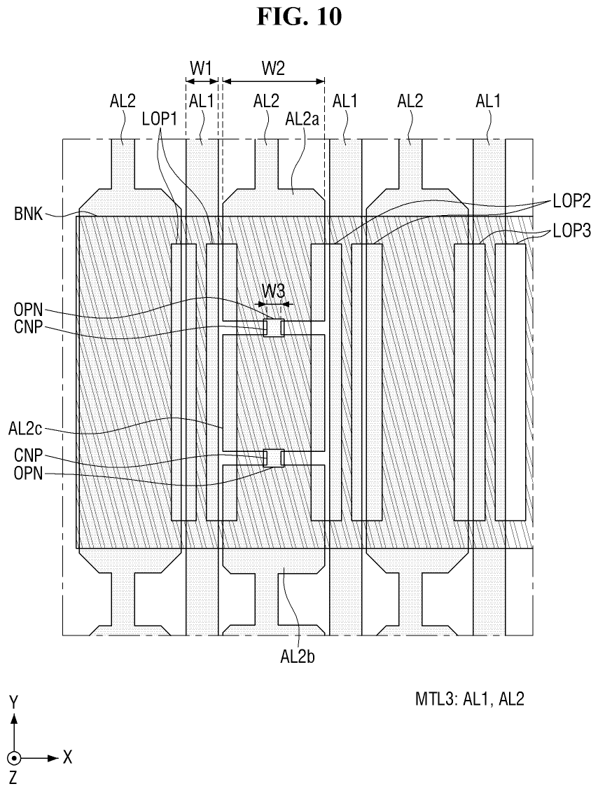

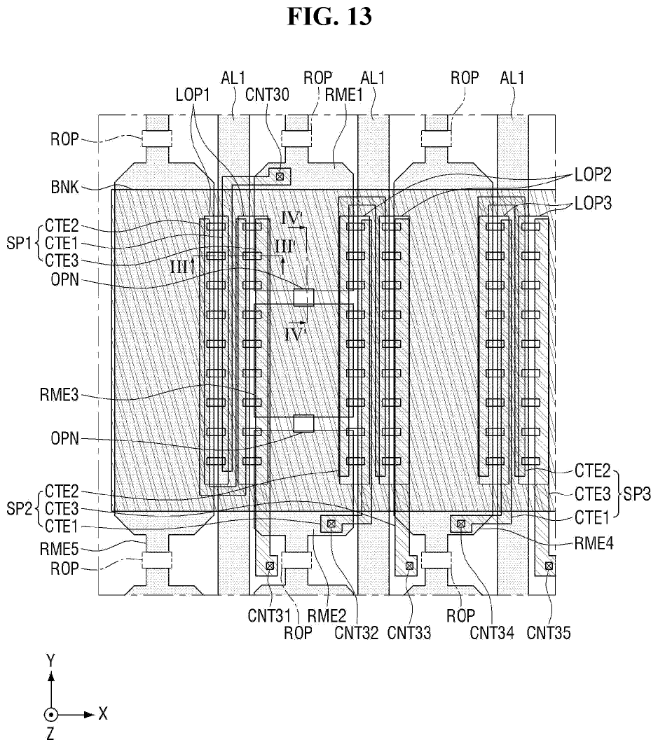

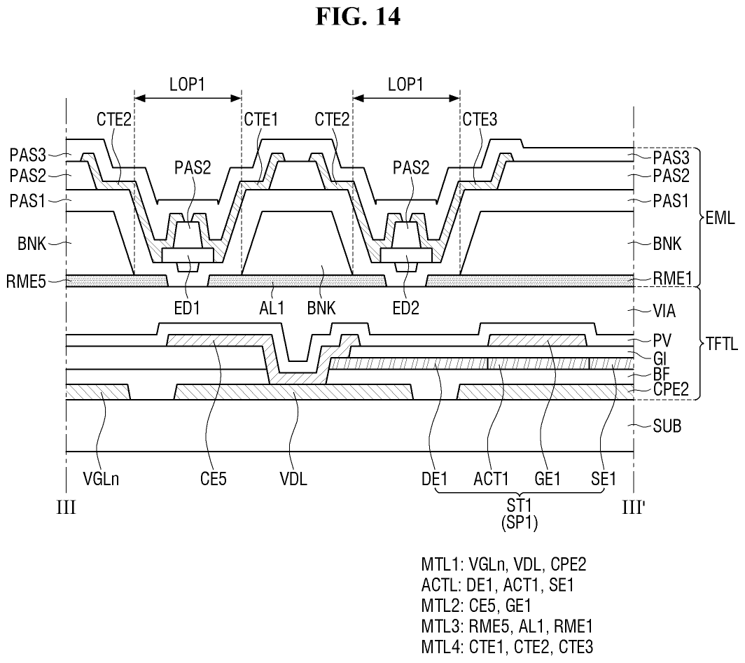

FIG. 9 is a schematic plan view illustrating a first metal layer, an active layer, a second metal layer, a third metal layer MTL3 and a bank in a display device according to an embodiment. FIG. 9 is a schematic view in which the third metal layer MTL3 and the bank are added to FIGS. 5 and 6. FIGS. 10 to 13 are schematic diagrams illustrating a manufacturing process of a light emitting element layer in a display device according to an embodiment. FIG. 14 is a schematic cross-sectional view taken along line III-III′ of FIGS. 9 and 13 and FIG. 15 is a schematic cross-sectional view taken along line IV-IV′ of FIGS. 9 and 13. Elements identical to those described above will be briefly described or will not be described below.

Referring to FIGS. 9 to 15, a light emitting element layer EML of the display device 10 may be disposed on a thin film transistor layer TFTL. The light emitting element layer EML may include first and second alignment lines AL1 and AL2, first to fifth electrodes RME1, RME2, RME3, RME4, and RME5, a bank BNK, a first insulating layer PAS1, first and second light emitting elements ED1 and ED2, a second insulating layer PAS2, contact electrodes CTE1, CTE2, and CTE3, and a third insulating layer PAS3. Here, the first to fifth electrodes RME1, RME2, RME3, RME4, and IMES may be formed by separating the second alignment line AL2. For example, the contact electrodes CTE1, CTE2, and CTE3 may include a first contact electrode CTE1, an intermediate contact electrode CTE2, and a second contact electrode CTE3.

In FIG. 10, the first alignment line AU may be disposed in (or formed of) the third metal layer MTH on the via layer VIA. The first alignment lines AL1 may extend in the second direction (e.g., Y-axis direction) and may be spaced apart from each other in the first direction (e.g., X-axis direction). The first alignment line AL1 may be disposed between the second alignment lines AL2. Each of the first alignment lines AL1 may be connected (e.g., electrically connected) to the horizontal voltage line HDL through the twenty-sixth contact hole CNT26 of FIG. 6. The first alignment line AL1 may receive a high potential voltage or a first alignment signal from the horizontal voltage line HVDL. The width W1 of the first alignment line AL1 may be smaller than the width W2 of the second alignment line AL2 but embodiments are not limited thereto.

The second alignment line AL2 may be disposed in (or formed of) the third metal layer MTL3. The second alignment lines AL2 may extend in the second direction (e.g., Y-axis direction) and may be spaced apart from each other in the first direction (e.g., X-axis direction). The second alignment line AL2 may be disposed between the first alignment lines AU. Each of the second alignment lines AL2 may be connected (e.g., electrically connected) to the second voltage line VSL through the twenty-seventh to twenty-ninth contact holes CNT27 to CNT29 of FIG. 6. The second alignment line AL2 may receive a low potential voltage or a second alignment signal from the second voltage line VSL.

At least one second alignment line AL2 among the second alignment lines AL2 may include first to third portions AL2a, AL2b, and AL2c. The first portion AL2a of the second alignment line AL2 may overlap the pixel circuit PXC of the first pixel SP1, the second portion AL2b of the second alignment line AL2 may overlap the pixel circuit PXC of the second pixel SP2, and the third portion AL2c of the second alignment line AL2 may overlap the pixel circuit PXC of the third pixel SP3. The third portion AL2c of the second alignment line AL2 may be disposed between the first portion AL2a and the second portion AL2b. The first portion AL2a and the third portion AL2c of the second alignment line AL2 may be adjacent to each other in the second direction (e.g., Y-axis direction) and may be connected (e.g., electrically connected) to each other through a connection portion CNP. The third portion AL2c and the second portion AL2b of the second alignment line AL2 may be adjacent to each other in the second direction (e.g., Y-axis direction) and may be connected (e.g., electrically connected) to each other through the connection portion CNP. A width W3 of the connection portion CNP in the first direction (e.g., X-axis direction) may be smaller than a width W2 of each of the first to third portions AL2a, AL2b, and AL2c in the first direction (e.g., X-axis direction). The connection portion CNP may be exposed by an open portion OPN of the bank BNK.

The bank BNK may be disposed on the via layer VIA and the first and second alignment lines AL1 and AL2. The bank BNK may include first to third light emitting openings LOP1, LOP2, and LOP3 and the open portion OPN.

The first light emitting openings LOP1 may extend in the second direction (e.g., Y-axis direction) and may be spaced apart from each other in the first direction (e.g., X-axis direction). Each of the first light emitting openings LOP1 may overlap an area between the first and second alignment lines AL1 and AL2. Each of the first light emitting openings LOP1 may expose edge portions of the first and second alignment lines AL1 and AL2.

The second light emitting openings LOP2 may extend in the second direction (e.g., Y-axis direction) and may be spaced apart from each other in the first direction (e.g., X-axis direction). Each of the second light emitting openings LOP2 may overlap an area between the first and second alignment lines AL1 and AL2. Each of the second light emitting openings LOP2 may expose edge portions of the first and second alignment lines AL1 and AL2.

The third light emitting openings LOP3 may extend in the second direction (e.g., Y-axis direction) and may be spaced apart from each other in the first direction (e.g., X-axis direction). Each of the third light emitting openings LOP3 may overlap an area between the first and second alignment lines AL1 and AL2. Each of the third light emitting openings LOP3 may expose edge portions of the first and second alignment lines AL1 and AL2.

The open portion OPN may be disposed between the first and second light emitting openings LOP1 and LOP2. The open portion OPN may expose the connection portion CNP of the second alignment line AL2. The open portion OPN may be disposed between the pixel circuit PXC of the first pixel SP1 and the pixel circuit PXC of the third pixel SP3 on a plane, and the pixel circuit PXC of the third pixel SP3 and the pixel circuit PXC of the second pixel SP2. The open portion OPN may be disposed between the first portion AL2a and the third portion AL2c of the second alignment line AL2 and between the third portion AL2c and the second portion AL2b of the second alignment line AL2.

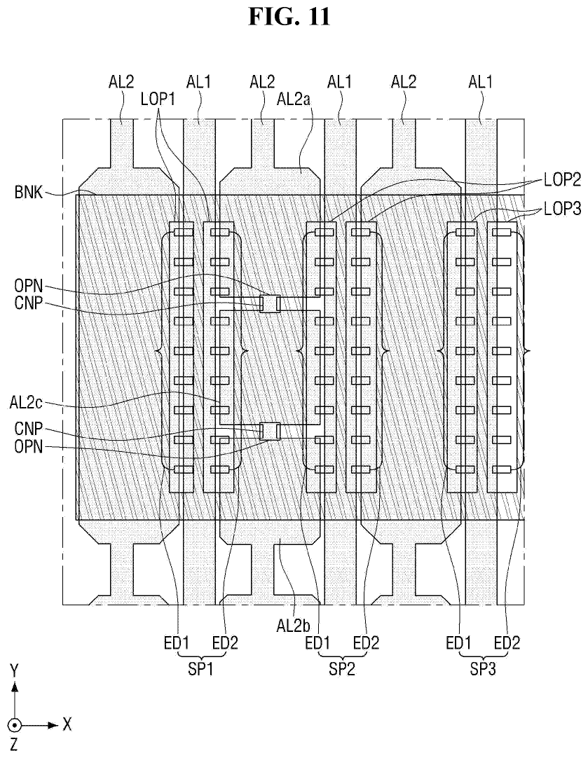

In FIG. 11, the light emitting elements ED may be disposed in the first to third light emitting openings LOP1, LOP2, and LOP3. The light emitting elements ED may be aligned between the first alignment line AL1 and the second alignment line AL2. For example, the second alignment line AL2 may include first to third electrodes RME1, RME2, and RME3, which are funned by dividing (or separating) the second alignment line AL2 (see, e.g., FIG. 13). For example, the light emitting elements ED may be aligned between the first alignment line AL1 and the first electrode RME1, aligned between the first alignment line AL1 and the second electrode RME2, and aligned between the first alignment line AL1 and the third electrode RME3 (see, e.g., FIG. 13). The first alignment line AL1 may receive the first alignment signal, the second alignment line AL2 may receive the second alignment signal, and an electric field may be formed between the first and second alignment lines AL1 and AL2. For example, the light emitting elements ED may be sprayed (or injected) on the first and second alignment lines AL1 and AL2 through an inkjet printing process, and the light emitting elements ED dispersed in the ink may receive a dielectrophoresis force for alignment due to electric field formed between the first and second alignment lines AL1 and AL2. Accordingly, the light emitting elements ED may be aligned along the second direction (e.g., Y-axis direction) between the first and second alignment lines AL1 and AL2.

The light emitting element ED of the first pixel SP1 may be disposed in the first light emitting opening LOP1. The first light emitting elements ED1 of the first pixel SP1 may be disposed in the first light emitting opening LOP1 on the left side, and the second light emitting elements ED2 of the first pixel SP1 may be disposed in the first light emitting opening LOP1 on the right side.

The light emitting element ED of the second pixel SP2 may be disposed in the second light emitting opening LOP2. The first light emitting elements ED1 of the second pixel SP2 may be disposed in the second light emitting opening LOP2 on the left side, and the second light emitting elements ED2 of the second pixel SP2 may be disposed in the second light emitting opening LOP2 on the right side.

The light emitting element ED of the third pixel SP3 may be disposed in the third light emitting opening LOP3. The first light emitting elements ED1 of the third pixel SP3 may be disposed in the third light emitting opening LOP3 on the left side, and the second light emitting elements ED2 of the third pixel SP3 may be disposed in the third light emitting opening LOP3 on the right side.

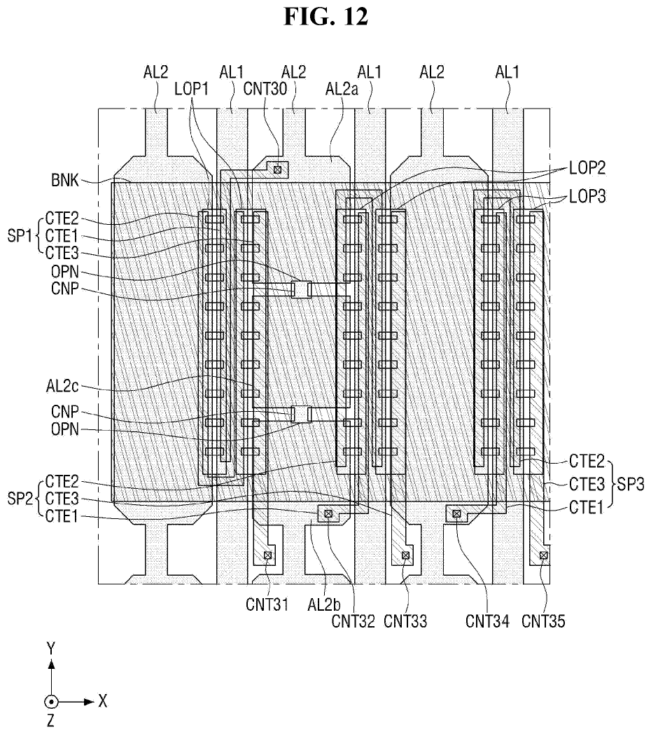

In FIG. 12, the contact electrodes CTE1, CTE2, and CTE3 of each of the first to third pixels SP1, SP2, and SP3 may be disposed in (or formed of) a fourth metal layer MTL4.

The first pixel SP1 may include contact electrodes CTE1, CTE2, and CTE3. A first contact electrode CTE1 of the first pixel SP1 may be connected (e.g., electrically connected) to the first portion AL2a of the second alignment line AL2 through a thirtieth contact hole CNT30. The first contact electrode CTE1 may extend in the second direction (e.g., Y-axis direction) and may overlap the first alignment line AL1. The first contact electrode CTE1 may be connected between the first portion AL2a of the second alignment line AL2 and an end portion of the first light emitting elements ED1. The first contact electrode CTE1 may correspond to the anode electrode of the first light emitting elements ED1, but embodiments are not limited thereto.

The intermediate contact electrode CTE2 of the first pixel SP1 may be insulated from the first and second alignment lines AL1 and AL2. The first portion of the intermediate contact electrode CTE2 may be disposed on the first and second alignment lines AL1 and AL2 to extend in the second direction (e.g., Y-axis direction). The second portion of the intermediate contact electrode CTE2 may be disposed on the first alignment line AL1 to extend in the second direction (e.g., Y-axis direction). The intermediate contact electrode CTE2 may be connected between the other end portions of the first light emitting elements ED1 and end portions of the second light emitting elements ED2. The intermediate contact electrode CTE2 may correspond to the third node N3 of FIG. 4. The intermediate contact electrode CTE2 may correspond to cathode electrodes of the first light emitting elements ED1, but embodiments are not limited thereto. The intermediate contact electrode CTE2 may correspond to the anode electrodes of the second light emitting elements ED2, but embodiments are not limited thereto.

A second contact electrode CTE3 may be connected (e.g., electrically connected) to the second voltage line VSL through the thirty-first contact hole CNT31. The second contact electrode CTE3 may extend in the second direction (e.g., Y-axis direction) and may overlap the second alignment line AL2. The second contact electrode CTE3 may be connected between the other end portion of the second light emitting element ED2 and the second alignment line AL2. The second contact electrode CTE3 may correspond to cathode electrodes of the second light emitting elements ED2, but embodiments are not limited thereto. The second contact electrode CTE3 may receive low potential voltage through the second voltage line VSL.

The second pixel SP2 may include contact electrodes CTE1, CTE2, and CTE3. The first contact electrode CTE1 of the second pixel SP2 may be connected (e.g., electrically connected) to the second portion AL2b of the second alignment line AL2 through a thirty-second contact hole CNT32. The first contact electrode CTE1 may be connected between the second portion AL2b of the second alignment line AL2 and end portions of the first light emitting elements ED1. The intermediate contact electrode CTE2 may be connected between the other end portions of the first light emitting elements ED1 and end portions of the second light emitting elements ED2. The second contact electrode CTE3 may be connected (e.g., electrically connected) to the second voltage line VSL through the thirty-third contact hole CNT33. The second contact electrode CTE3 may be connected between the other end portion of the second light emitting element ED2 and the second alignment line AL2.

The third pixel SP3 may include contact electrodes CTE1, CTE2, and CTE3. The first contact electrode CTE1 of the third pixel SP3 may be connected (e.g., electrically connected) to the second alignment line AL2 through a thirty-fourth contact hole CNT34. The first contact electrode CTE1 may be connected between the second alignment line AL2 and end portions of the first light emitting elements ED1. The intermediate contact electrode CTE2 may be connected between the other end portions of the first light emitting elements ED1 and end portions of the second light emitting elements ED2. The second contact electrode CTE3 may be connected (e.g., electrically connected) to the second voltage line VSL through the thirty-fifth contact hole CNT35. The second contact electrode CTE3 may be connected between the other end portion of the second light emitting element ED2 and the second alignment line AL2.

In FIG. 13, the second alignment lines AL2 may be separated in units of rows by a separation portion ROP.

The connection portion CNP of the second alignment line AL2 may be exposed by the open portion OPN of the bank BNK and may be removed after the alignment process of the light emitting elements ED is completed. Accordingly, the first to third portions AL2a, AL2b, and AL2c of the second alignment line AL2 may be separated or divided from each other.

The first portion AL2a of the second alignment line AL2 may be separated to form the first electrode RME1. The first electrode RME1 may overlap the pixel circuit PXC of the first pixel SP1. The first electrode RME1 may be connected (e.g., electrically connected) to the sixth connection electrode CE6 through the seventh contact hole CNT7, and the sixth connection electrode CE6 may be connected (e.g., electrically connected) to the second capacitor electrode CPE2 through the sixth contact hole CNT6 (see, e.g., FIGS. 6 and 9). The first electrode RME1 may be connected (e.g., electrically connected) to the first contact electrode CTE1 through the thirtieth contact hole CNT30. The first electrode RME1 may supply a driving current received from the pixel circuit PXC of the first pixel SP1 to the first contact electrode CTE1.

The first electrode RME1 may face the first capacitor electrode CPE1 of the active layer ACTL. The first capacitor C1 may be formed between the first capacitor electrode CPE1 and the second capacitor electrode CPE2, and may also be formed between the first capacitor electrode CPE1 and the first electrode RME1. Accordingly, the display device 10 may overlap the first electrode RME1 of the third metal layer MTL3 with the first capacitor electrode CPE1 of the active layer ACTL, and may connect (e.g., electrically connect) the first electrode RME1 of the third metal layer MTL3 to the second capacitor electrode CPE2 of the first metal layer MTL1, thereby forming the first capacitor C1 as a double to ensure capacitance and reduce coupling capacitance between pixel circuits PXC. The display device 10 may include the first capacitor electrode CPE1 of the first pixel SP1 covered by the first electrode RME1, thereby minimizing variation due to the coupling capacitor of the first capacitor electrode CPE1 and preventing horizontal crosstalk (or coupling) to improve image quality.

The second portion AL2b of the second alignment line AL2 may be separated to form the second electrode RME2. The second electrode RME2 may overlap the pixel circuit PXC of the second pixel SP2. The second electrode RME2 may be connected (e.g., electrically connected) to the twelfth connection electrode CE12 through the fifteenth contact hole CNT15, and the twelfth connection electrode CE12 may be connected (e.g., electrically connected) to the second capacitor electrode CPE2 through the fourteenth contact hole CNT14 (see, e.g., FIGS. 6 and 9). The second electrode RME2 may be connected (e.g., electrically connected) to the first contact electrode CTE1 through the thirty-second contact hole CNT32 (see, e.g., FIGS. 12 and 13). The second electrode RME2 may supply a driving current received from the pixel circuit PXC of the second pixel SP2 to the first contact electrode CTE1.

The second electrode RME2 may face the first capacitor electrode CPE1 of the active layer ACTL. The first capacitor C1 may be formed between the first capacitor electrode CPE1 and the second capacitor electrode CPE2, and may also be formed between the first capacitor electrode CPE1 and the second electrode RME2. Accordingly, the display device 10 may overlap the second electrode RME2 of the third metal layer MTL3 with the first capacitor electrode CPE1 of the active layer ACTL, and may connect (e.g., electrically connect) the second electrode RME2 of the third metal layer MTL3 to the second capacitor electrode CPE2 of the first metal layer MTL1, thereby forming the first capacitor C1 as a double to ensure capacitance and reduce coupling capacitance between pixel circuits PXC. The display device 10 may include the first capacitor electrode CPE1 of the second pixel SP2 covered by the second electrode RME2, thereby minimizing variation due to the coupling capacitor of the first capacitor electrode CPE1 and preventing horizontal crosstalk (or coupling) to improve image quality.

The third portion AL2c of the second alignment line AL2 may be separated to form the third electrode RME3. The third electrode RME3 may overlap the pixel circuit PXC of the third pixel SP3. The third electrode RME3 may be connected (e.g., electrically connected) to the seventeenth connection electrode CE17 through the twenty-first contact hole CNT21, and the seventeenth connection electrode CE17 may be connected (e.g., electrically connected) to the second capacitor electrode CPE2 through the twentieth contact hole CNT20 (see, e.g., FIGS. 6 and 9).

The third electrode RME3 may face the first capacitor electrode CPE1 of the active layer ACTL. The first capacitor C1 may be formed between the first capacitor electrode CPE1 and the second capacitor electrode CPE2, and may also be formed between the first capacitor electrode CPE1 and the third electrode RME3. Accordingly, the display device 10 may overlap the third electrode RME3 of the third metal layer MTL3 with the first capacitor electrode CPE1 of the active layer ACTL, and may connect (e.g., electrically connect) the third electrode RME3 of the third metal layer MTL3 to the second capacitor electrode CPE2 of the first metal layer MTL1, thereby forming the first capacitor C1 as a double to ensure capacitance and reduce coupling capacitance between pixel circuits PXC. The display device 10 may include the first capacitor electrode CPE1 of the third pixel SP3 covered by the third electrode RME3, thereby minimizing variation due to the coupling capacitor of the first capacitor electrode CPE1 and preventing horizontal crosstalk (or coupling) to improve image quality.

The second alignment line AL2 may be separated to form the fourth electrode RME4. The fourth electrode RME4 may overlap the initialization voltage line VIL and the first to third data lines DL1, DL2, and DL3. The fourth electrode RME4 may be connected (e.g., electrically connected) to the eighteenth connection electrode CE18 through the twenty-third contact hole CNT23, and the eighteenth connection electrode CE18 may be connected (e.g., electrically connected) to the second capacitor electrode CPE2 through the twenty-second contact hole CNT22 (see, e.g., FIGS. 6 and 9). The fourth electrode RME4 may be connected (e.g., electrically connected) to the first contact electrode CTE1 of the third pixel SP3 through the thirty-fourth contact hole CNT34. The fourth electrode RME4 may supply a driving current received from the pixel circuit PXC of the third pixel SP3 to the first contact electrode CTE1.

The second alignment line AL2 may be separated to form the fifth electrode RME5. The fifth electrode RME5 may overlap the (n−1)^{th} and n^{th} vertical gate lines VGLn−1 and VGLn. The fifth electrode RME5 may be connected (e.g., electrically connected) to the sixth connection electrode CE6 through the eighth contact hole CNT8, and the sixth connection electrode CE6 may be connected (e.g., electrically connected) to the second capacitor electrode CPE2 through the sixth contact hole CNT6 (see, e.g., FIGS. 6 and 9).

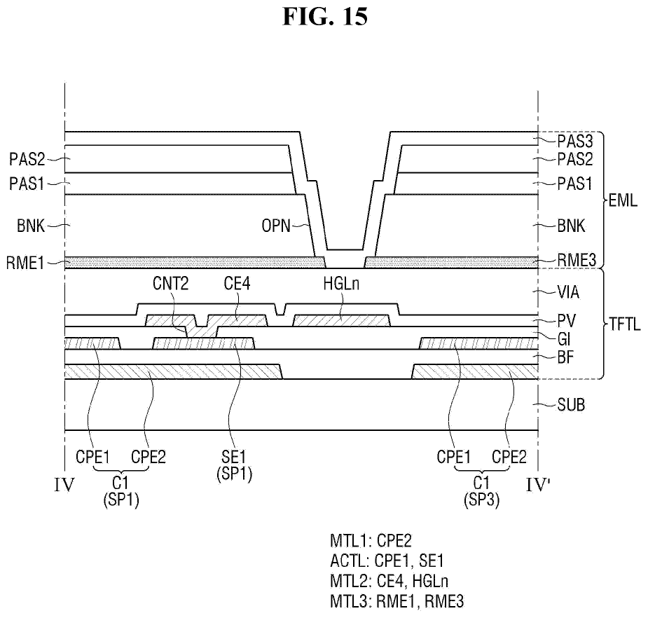

In FIGS. 14 and 15, the first insulating layer PAS1 may be disposed on the via layer VIA, the third metal layer MTL3, and the bank BNK. The first insulating layer PAS1 may insulate the third metal layer MTL3 from the light emitting element ED. The second insulating layer PAS2 may be disposed on the top portion of the light emitting element ED and the first insulating layer PAS1. The third insulating layer PAS3 may be disposed on the second insulating layer PAS2 and the fourth metal layer MTL4. The second and third insulating layers PAS2 and PAS3 may insulate each of the contact electrodes CTE1, CTE2, and CTE3.

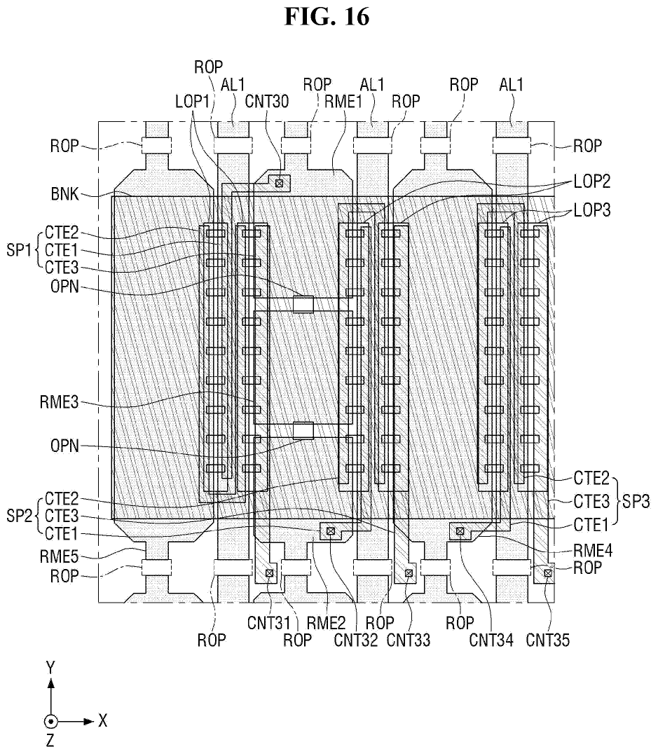

FIG. 16 is a schematic plan view illustrating a third metal layer, a bank, a light emitting element, a fourth metal layer and a separation portion in a display device according to an embodiment. A display device of FIG. 16 is different in configurations of separation portion ROP of the first alignment line AL1 from the display device of FIG. 13, and the same configurations as the configurations described above will be briefly described or a description therefor will be omitted.

Referring to FIG. 16, the first and second alignment lines AL1 and AL2 may be disposed on the third metal layer MTL3 on the via layer VIA. The first and second alignment lines AL1 and AL2 may be separated in units of rows by the separation portion ROP.

The first alignment line AL1 may be separated in units of rows to form an anode electrode of the light emitting elements ED, but embodiments are not limited thereto.

By separating in units of rows and removing the connection portion CNP, the second alignment line AL2 may become the first to fifth electrodes RME1, RME2, RME3, RME4, and RME5.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a pixel circuit of a first pixel formed of:
a first metal layer disposed on a substrate,
an active layer disposed on the first metal layer, and
a second metal layer disposed on the active layer;
a first electrode formed of a third metal layer disposed on the second metal layer, the first electrode overlapping the pixel circuit of the first pixel;
a pixel circuit of a second pixel spaced apart from the pixel circuit of the first pixel in a first direction, the pixel circuit of the second pixel formed of:
the first metal layer,
the active layer, and
the second metal layer;
a second electrode formed of the third metal layer and overlapping the pixel circuit of the second pixel;
an alignment line formed of the third metal layer and extending in the first direction; and
a plurality of light emitting elements disposed on the third metal layer, the plurality of light emitting elements aligned between the alignment line and the first electrode and aligned between the alignment line and the second electrode.

2. The display device of claim 1, wherein
the pixel circuit of the first pixel comprises:
a first capacitor electrode formed of the active layer, and
a second capacitor electrode formed of the first metal layer, and
the first electrode overlaps the first capacitor electrode of the first pixel and is electrically connected to the second capacitor electrode of the first pixel.

3. The display device of claim 1, further comprising:
a low potential line formed of the second metal layer and extending in a second direction intersecting the first direction;
a first contact electrode formed of a fourth metal layer disposed on the third metal layer, the first contact electrode connected between the first electrode and the plurality of light emitting elements; and
a second contact electrode formed of the fourth metal layer, the second contact electrode connected between the plurality of light emitting elements and the low potential line.

4. The display device of claim 1, further comprising:
a pixel circuit of a third pixel disposed between the pixel circuit of the first pixel and the pixel circuit of the second pixel, the pixel circuit of the third pixel formed of:
the first metal layer,
the active layer, and
the second metal layer; and
a third electrode formed of the third metal layer and overlapping the pixel circuit of the third pixel.

5. The display device of claim 4, further comprising:
a fourth electrode formed of the third metal layer and spaced apart from the third electrode, the fourth electrode connected to the pixel circuit of the third pixel,
wherein the alignment line is disposed between the third electrode and the fourth electrode.

6. The display device of claim 1, wherein
the pixel circuit of the second pixel comprises:
a first capacitor electrode formed of the active layer, and
a second capacitor electrode formed of the first metal layer, and
the second electrode overlaps the first capacitor electrode of the second pixel and is electrically connected to the second capacitor electrode of the second pixel.

7. The display device of claim 1, further comprising:
a bank disposed on the first electrode and the second electrode, the bank comprising an open portion disposed between the first electrode and the second electrode.

8. The display device of claim 7, wherein
the bank further comprises a light emitting opening extending in the first direction, and
the plurality of light emitting elements are disposed in the light emitting opening.

9. The display device of claim 1, further comprising:
a gate line formed of the second metal layer and extending in a second direction intersecting the first direction, the gate line that supplies a gate signal to the pixel circuit of the first pixel and the pixel circuit of the second pixel,
wherein the gate line is disposed between the pixel circuit of the first pixel and the pixel circuit of the second pixel.

10. A display device, comprising:
a pixel circuit of a first pixel formed of:
a first metal layer disposed on a substrate,
an active layer disposed on the first metal layer, and
a second metal layer disposed on the active layer;
a first electrode formed of a third metal layer disposed on the second metal layer, the first electrode overlapping the pixel circuit of the first pixel;
a pixel circuit of a second pixel formed of:
the first metal layer,
the active layer, and
the second metal layer and spaced apart from the pixel circuit of the first pixel in a first direction;
a second electrode formed of the third metal layer and overlapping the pixel circuit of the second pixel; and
a bank disposed on the first electrode and the second electrode, the bank comprising an open portion disposed between the first electrode and the second electrode.

11. The display device of claim 10, further comprising:
an alignment line formed of the third metal layer and spaced apart from the first electrode and the second electrode in a second direction intersecting the first direction; and
a plurality of light emitting elements aligned between the alignment line and the first electrode.

12. The display device of claim 11, wherein
the bank further comprises a light emitting opening overlapping an area between the alignment line and the first electrode, and
the plurality of light emitting elements are disposed in the light emitting opening.

13. The display device of claim 11, further comprising:
a low potential line formed of the second metal layer and extending in the second direction intersecting the first direction;
a first contact electrode formed of a fourth metal layer disposed on the third metal layer, the first contact electrode connected between the first electrode and the plurality of light emitting elements; and
a second contact electrode formed of the fourth metal layer, the second contact electrode connected between the plurality of light emitting elements and the low potential line.

14. The display device of claim 10, further comprising:
an alignment line formed of the third metal layer and spaced apart from the first electrode and the second electrode in a second direction intersecting the first direction; and
a plurality of light emitting elements aligned between the alignment line and the second electrode.

15. The display device of claim 14, further comprising:
a low potential line formed of the second metal layer and extending in the second direction intersecting the first direction;
a first contact electrode formed of a fourth metal layer disposed on the third metal layer and connected between the second electrode and the plurality of light emitting elements; and
a second contact electrode formed of the fourth metal layer and connected between the plurality of light emitting elements and the low potential line.

16. The display device of claim 10, wherein
the pixel circuit of the first pixel comprises a first capacitor electrode formed of the active layer and a second capacitor electrode formed of the first metal layer, and
the first electrode overlaps the first capacitor electrode of the first pixel and is electrically connected to the second capacitor electrode of the first pixel.

17. The display device of claim 10, wherein
the pixel circuit of the second pixel comprises a first capacitor electrode formed of the active layer and a second capacitor electrode formed of the first metal layer, and
the second electrode overlaps the first capacitor electrode of the second pixel and is electrically connected to the second capacitor electrode of the second pixel.

18. A display device comprising:
a first voltage line formed of a first metal layer disposed on a substrate;
a first transistor comprising:
a drain electrode formed of an active layer disposed on the first metal layer, the drain electrode electrically connected to the first voltage line,
a source electrode formed of the active layer, and
a gate electrode formed of a second metal layer disposed on the active layer;
a first capacitor electrode formed of the active layer and electrically connected to the gate electrode of the first transistor;
a second capacitor electrode formed of the first metal layer and overlapping the first capacitor electrode;
a first electrode formed of a third metal layer disposed on the second metal layer, the first electrode overlapping the first capacitor electrode and electrically connected to the second capacitor electrode;
an alignment line formed of the third metal layer and extending in a first direction; and
a plurality of light emitting elements aligned between the alignment line and the first electrode disposed on the third metal layer.

19. The display device of claim 18, further comprising:
a data line formed of the first metal layer and extending in the first direction; and
a second transistor electrically connecting the data line and the first capacitor electrode.

20. The display device of claim 19, further comprising:
an initialization voltage line formed of the first metal layer and extending in the first direction; and
a third transistor electrically connecting the initialization voltage line and the second capacitor electrode.
